(19) United States
(12) Patent Application Publication
(10) Pub. No.: US 2025/0373237 A1
(43) Pub. Date: Dec. 4, 2025

(54) METHODS AND APPARATUS TO DRIVE INDUCTOR-CAPACITOR (LC) CIRCUITRY WITH SUBHARMONIC INJECTION

(71) Applicant: Texas Instruments Incorporated, Dallas, TX (US)

(72) Inventors: Karthikeyan Gunasekaran, Bangalore (IN); Prajjwal Rana, Aligarh (IN); Jagannathan Venkataraman, Bangalore (IN); Viswanathan Nagarajan, Bangalore (IN)

(21) Appl. No.: 18/680,701

(22) Filed: May 31, 2024

(51) Int. Cl. H03K 5/04; H03K 3/017; H03K 5/125; H03K 17/687

(52) U.S. Cl. CPC H03K 5/04; H03K 3/017; H03K 5/125; H03K 17/6871

(57) ABSTRACT

An example apparatus includes: first current source circuitry having a terminal; a first transistor having a first terminal, a second terminal, and a control terminal, the first terminal of the first transistor coupled to the terminal of the first current source circuitry, the control terminal of the first transistor coupled to the terminal of the first frequency multiplier circuitry; second current source circuitry having a terminal; a second transistor having a first terminal and a second terminal, the first terminal of the second transistor coupled to the terminal of the second current source circuitry; an inductor having a first terminal and a second terminal; a capacitor having a first terminal and a second terminal, the first terminal of the capacitor coupled to the first terminal of the inductor; and an amplifier having a terminal coupled to the second terminal of the first transistor, the second terminal of the second transistor.

### TECHNICAL FIELD

This description relates generally to driving inductor-capacitor (LC) circuitry and, more particularly, to methods and apparatus to drive LC circuitry with subharmonic injection.

### BACKGROUND

As electronics continue to become increasingly complex, circuitry has become capable of operating at high speeds with decreasing package sizes. Transmission speeds of communication systems continue to increase as electronics continue to advance. Thus, transmitter circuitry has to accurately generate transmission signals at high speeds based on clock circuitry that generates accurate, high-frequency clock signals. The clock circuitry generates a high-frequency clock signal by multiplying a relatively lower frequency clock signal. The high-frequency clock signal allows the transmitter circuitry to accurately generate transmissions at high frequencies.

### SUMMARY

For methods and apparatus to drive LC circuitry with subharmonic injection, an example apparatus includes first frequency multiplier circuitry having a terminal; and second frequency multiplier circuitry including: first current source circuitry having a terminal; a first transistor having a first terminal, a second terminal, and a control terminal, the first terminal of the first transistor coupled to the terminal of the first current source circuitry, the control terminal of the first transistor coupled to the terminal of the first frequency multiplier circuitry; second current source circuitry having a terminal; a second transistor having a first terminal and a second terminal, the first terminal of the second transistor coupled to the terminal of the second current source circuitry; an inductor having a first terminal and a second terminal; a capacitor having a first terminal and a second terminal, the first terminal of the capacitor coupled to the first terminal of the inductor; and an amplifier having a terminal coupled to the second terminal of the first transistor, the second terminal of the second transistor, the second terminal of the inductor, and the second terminal of the capacitor. Other examples are described.

For methods and apparatus to drive LC circuitry with subharmonic injection, an example apparatus includes first frequency multiplier circuitry having a terminal; and second frequency multiplier circuitry having a first terminal and a second terminal, the first terminal of the second frequency multiplier circuitry coupled to the terminal of the first frequency multiplier circuitry, the second frequency multiplier circuitry configured to generate a clock signal having a duty cycle; duty cycle estimation circuitry having a first terminal and a second terminal, the duty cycle estimation circuitry configured to estimate the duty cycle of the clock signal; and duty cycle correction circuitry having a first terminal, a second terminal, and a third terminal, the first terminal of the duty cycle correction circuitry coupled to the second terminal of the second frequency multiplier circuitry, the second terminal of the duty cycle correction circuitry coupled to the first terminal of the duty cycle estimation circuitry, the third terminal of the duty cycle correction circuitry is coupled to the second terminal of the duty cycle estimation circuitry, the duty cycle correction circuitry configured to adjust the duty cycle of the clock signal responsive to the estimate of the duty cycle from the duty cycle estimation circuitry. Other examples are described.

For methods and apparatus to drive LC circuitry with subharmonic injection, an example apparatus includes clock multiplier circuitry configured to multiply a frequency of a first clock signal to generate a second clock signal; and injection multiplication circuitry coupled to the clock multiplier circuitry, the injection multiplication circuitry configured to: generate an injection current responsive to amplitudes of the second clock signal; modify a resonant frequency of the injection multiplication circuitry by supplying the injection current; and generate a third clock signal having a frequency set by the resonant frequency. Other examples are described.

### BRIEF DESCRIPTION OF THE DRAWINGS

FIG. 1 is a block diagram of an example communication system including clock circuitry further having clock multiplier circuitry, injection multiplication circuitry, duty cycle correction circuitry, and duty cycle estimation circuitry.

FIG. 2 is a schematic diagram of an example of the clock multiplier circuitry of FIG. 1 and an example of the injection multiplication circuitry of FIG. 1.

FIG. 3 is a flowchart representative of at least one of example machine-readable instructions or example operations that may be executed, instantiated, or performed to implement the clock multiplication circuitry of FIGS. 1 and 2 and the injection multiplication circuitry of FIGS. 1 and 2.

FIG. 4 is an example timing diagram of example operations of the clock multiplication circuitry of FIGS. 1 and 2.

FIGS. 5A and 5B are example timing diagrams of example operations of the injection lock circuitry of FIGS. 1 and 2.

FIG. 6 is a block diagram of an example of the duty cycle correction circuitry of FIG. 1 and an example of the duty cycle estimation circuitry of FIG. 1.

FIG. 7 is a schematic and block diagram of an example of the duty cycle correction circuitry of FIGS. 1 and 6.

FIG. 8 is a flowchart representative of at least one of example machine-readable instructions or example operations that may be executed, instantiated, or performed to implement the duty cycle correction circuitry of FIGS. 1, 6, and 7.

FIG. 9 is a timing diagram of example operations of the duty cycle correction circuitry of FIGS. 1, 6, and 7.

FIG. 10 is a schematic diagram of an example of the duty cycle estimation circuitry of FIGS. 1 and 6.

FIG. 11 is a flowchart representative of at least one of example machine-readable instructions or example operations that may be executed, instantiated, or performed to implement the duty cycle estimation circuitry of FIGS. 1, 6, and 10.

FIG. 12 is a timing diagram of example operations of the duty cycle estimation circuitry of FIGS. 1, 6, and 10.

FIG. 13 is another timing diagram of example operations of the duty cycle estimation circuitry of FIGS. 1, 6, and 10.

FIG. 14 is a plot of example operations of the duty cycle estimation circuitry of FIGS. 1, 6, and 10.

FIG. 15 is a block diagram of an example processing platform including programmable circuitry structured to execute, instantiate, or perform the example machine-readable instructions or perform the example operations of FIG. 11 to implement the coefficient controller circuitry of FIGS. 6 and 10.

FIG. 16 is a block diagram of an example implementation of the programmable circuitry of FIG. 15.

FIG. 17 is a block diagram of another example implementation of the programmable circuitry of FIG. 15.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to become increasingly complex, circuitry has become capable of operating at high speeds with decreasing package sizes. Transmission speeds of communication systems continue to increase as electronics continue to advance. Thus, transmitter circuitry has to accurately generate transmission signals at high speeds using clock circuitry that generates accurate, high-frequency clock signals. Some clock circuitry generates a high-frequency clock signal by multiplying a relatively lower frequency clock signal. The high-frequency clock signal allows the transmitter circuitry to accurately generate transmissions at high frequencies.

In some systems, such as communication systems, phase errors of the clock signal from the clock circuitry may result in transmission errors. In other systems, such as radar systems, phase errors of the clock signal from the clock circuitry may result in detection errors. As transmission speeds continue to increase, some clock circuitry designs use increasingly complex circuitry to reduce phase errors.

One method of implementing clock circuitry is to use a phase locked loop (PLL) design. PLL clock circuitry includes phase frequency detection (PFD) circuitry, charge pump circuitry, low pass filter circuitry, a voltage-controlled oscillator (VCO), and divider circuitry. The PFD circuitry receives an input clock signal and a frequency divided output clock signal from the divider circuitry. The frequency divided clock signal is proportional to the output clock signal. The PFD circuitry compares phases of the input clock signal to the divided output clock signal and generates an output signal representing the comparison. The low pass filter circuitry uses the charge pump circuitry to generate a control voltage responsive to the output of the PFD circuitry. The VCO generates the output clock signal proportional to the control voltage. However, the low pass filter circuitry generates the control voltage with relatively high noise, which the VCO then multiplies to generate the output clock signal. Substantially increasing the size of the charge pump, which increases the system on chip (SoC) size and cost, reduces the noise of the low pass filter circuitry and the VCO.

Another method of implementing clock circuitry is using a harmonic multiplication design. In a first implementation, harmonic multiplication circuitry uses harmonic multiplication to multiply the frequency of an input clock signal. In such designs, the input clock signal drives transistors (also referred to as injection circuitry) to inject a current into inductor-capacitor (LC) circuitry. Such a method of current injection is referred to as an injection lock. The LC circuitry has a resonant frequency specific to the target frequency of the output clock signal. However, capacitances of the transistors, which inject the current, modify the resonant frequency of the LC circuitry every time current is injected into the LC circuitry. However, when using the injection circuitry and the LC circuitry to multiply the frequency of an input clock signal, the injection circuitry injects current at the frequency of the input clock signal resulting in cycles of the output clock signal with no current injection. Such a method of injecting current at a frequency of the input clock signal to generate an output clock signal having a frequency that is a multiple of the input clock signal is referred to as subharmonic injection. In designs that use subharmonic injection, amplitudes of the output clock signal have a varying amplitude responsive to the lack of current injection at every cycle of the output clock signal. The variations in the amplitudes of the clock signal increase the phase errors of the output clock signal.

In harmonic multiplication designs, harmonic filter circuitry may be used to multiply the input clock signal by a second multiple. The harmonic filter generates a clock signal that has a frequency that is approximately equal to the desired frequency of the output clock signal. The injection circuitry uses the multiplied input clock signal from the harmonic filter circuitry to inject current at each cycle of the output clock signal. In this implementation, the frequency of the output clock signal is approximately equal to the frequency of the multiplied input clock signal from the harmonic filter circuitry. However, the harmonic filter circuitry generates noise due to using harmonic multiplication to increase the frequency by the second multiple. The injection circuitry generates the output clock signal having phase errors due to the noise from the harmonic filter circuitry.

Examples described herein include methods and apparatus to drive LC circuitry with subharmonic injection. In some described examples, clock circuitry includes clock multiplier circuitry, injection multiplication circuitry, duty cycle correction circuitry, and duty cycle estimation circuitry. The clock multiplier circuitry multiplies a clock signal by a first multiple. The injection multiplication circuitry uses current source circuitry, current injection circuitry, and LC circuitry to multiply the multiplied clock signal from the clock multiplier circuitry. The current source circuitry reduces variations in amplitudes of a clock signal by supplying a current that compensates the LC circuitry for dampening. The current injection circuitry injects current into the LC circuitry responsive to pulses of the multiplied clock signal from the clock multiplier circuitry. Advantageously, the current injection circuitry reduces variations in the amplitude of an output clock signal from the injection multiplication circuitry 145.

The duty cycle correction circuitry and the duty cycle estimation circuitry further reduce phase errors between cycles of the output clock signal from the injection multiplication circuitry. The duty cycle correction circuitry adjusts rising and falling edges of cycles of the output clock signal to decrease variations between duty cycles of the output clock signal. The duty cycle estimation circuitry adjusts the timing of the rising and falling edges of the duty cycle correction circuitry responsive to a detection of variations in duty cycles. Advantageously, the duty cycle correction circuitry and the duty cycle estimation circuitry reduce variations between duty cycles of the output clock signal from the injection multiplication circuitry. Advantageously, reducing variations between the duty cycles of the output clock signal decreases phase errors.

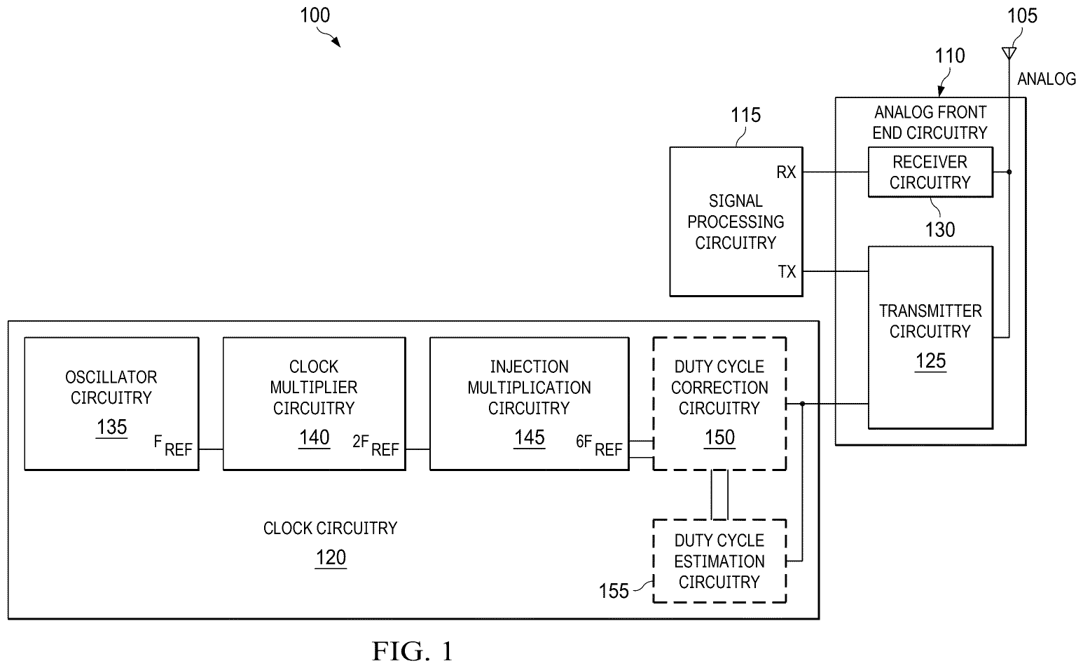

FIG. 1 is a block diagram of an example communication system 100. In the example of FIG. 1, the communication system includes an antenna 105, analog front end (AFE) circuitry 110, signal processing circuitry 115, and clock circuitry 120. The AFE circuitry 110 of FIG. 1 further includes example transmitter circuitry 125 and example receiver circuitry 130. The clock circuitry of FIG. 1 further includes example oscillator circuitry 135, example clock multiplier circuitry 140, example injection multiplication circuitry 145, example duty cycle correction circuitry 150, and example duty cycle estimation circuitry 155. In some examples, the communication system 100 is communicatively coupled to another instance of the communication system 100. In such examples, the communication system 100 transmits and receives data. In another example, the transmitter circuitry 125 is communicatively coupled to the receiver circuitry 130. In such examples, the communication system 100 is a radar system.

The antenna 105 has a terminal coupled to the AFE circuitry 110. The antenna 105 may be communicatively coupled to another communication system, which exchanges electromagnetic signals with the communication system 100 using the antenna 105. In some examples, a connector, such as a coaxal cable, couples the antenna 105 to the AFE circuitry 110. In such examples, the connector allows the antenna 105 and the AFE circuitry 110 to be located at separate locations.

The AFE circuitry 110 has a first terminal, a second terminal, a third terminal, and a fourth terminal. The first terminal of the AFE circuitry 110 is coupled to the antenna 105. The second and third terminals of the AFE circuitry 110 are coupled to the signal processing circuitry 115. The fourth terminal of the AFE circuitry 110 is coupled to the clock circuitry 120. In some examples, the communication system 100 may be modified to include additional components in the AFE circuitry 110. For example, the AFE circuitry 110 can include one or both of the signal processing circuitry 115 and the clock circuitry 120. The signal processing circuitry 115 has a first terminal and a second terminal coupled to the AFE circuitry 110. The signal processing circuitry 115 is communicatively coupled to the AFE circuitry 110. The clock circuitry 120 has a terminal coupled to the AFE circuitry 110. In some examples, the clock circuitry 120 has an additional terminal coupled to a crystal component.

The transmitter circuitry 125 has a first terminal, a second terminal, and a third terminal. The first terminal of the transmitter circuitry 125 is coupled to the antenna 105 and the receiver circuitry 130. The second terminal of the transmitter circuitry 125 is coupled to the signal processing circuitry 115. The third terminal of the transmitter circuitry 125 is coupled to the clock circuitry 120. The receiver circuitry 130 has a first terminal and a second terminal. The first terminal of the receiver circuitry 130 is coupled to the antenna 105 and the transmitter circuitry 125. The second terminal of the receiver circuitry 130 is coupled to the signal processing circuitry 115.

The oscillator circuitry 135 has a terminal coupled to the clock multiplier circuitry 140. In some examples, the oscillator circuitry 135 is crystal oscillator circuitry. In such examples, the oscillator circuitry 135 has an additional terminal coupled to a crystal component. In other examples, the oscillator circuitry is resistor-capacitor (RC) oscillator circuitry. Alternatively, the oscillator circuitry 135 is a different type of oscillator circuitry.

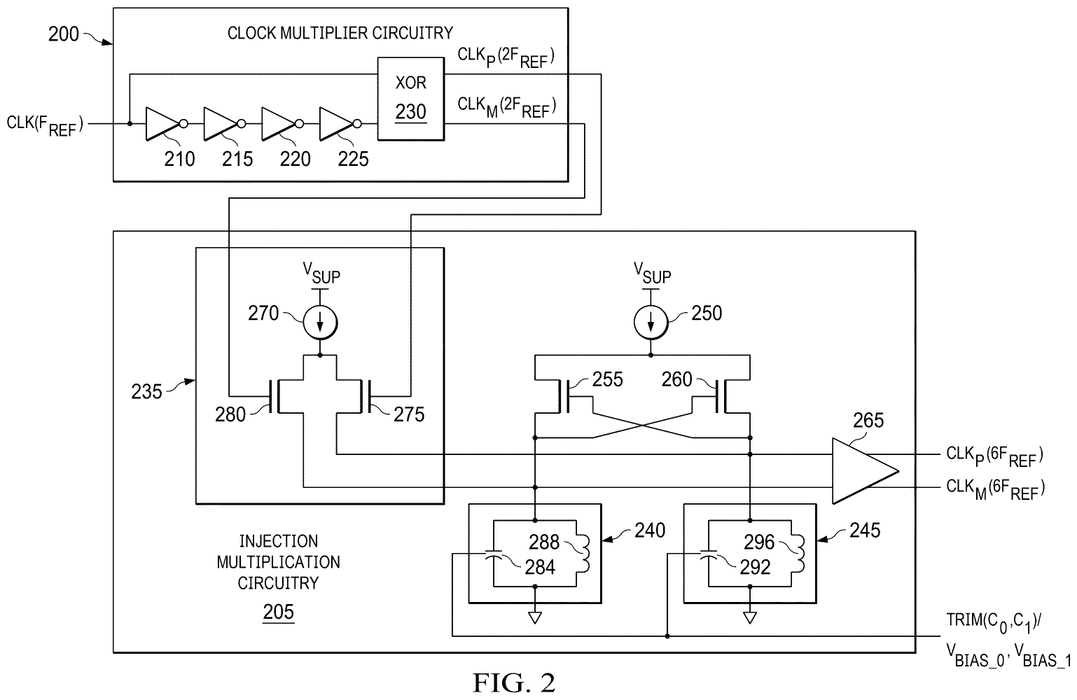

The clock multiplier circuitry 140 (also referred to as frequency multiplier circuitry) has a first terminal and a second terminal. The first terminal of the clock multiplier circuitry 140 is coupled to the oscillator circuitry 135. The second terminal of the clock multiplier circuitry 140 is coupled to the injection multiplication circuitry 145. An example implementation of the clock multiplier circuitry 140 is illustrated and described in connection with FIG. 2, below.

The injection multiplication circuitry 145 (also referred to as frequency multiplier circuitry) has a first terminal, a second terminal, and a third terminal. The first terminal of the injection multiplication circuitry 145 is coupled to the clock multiplier circuitry 140. The second and third terminals of the injection multiplication circuitry 145 are coupled to the duty cycle correction circuitry 150. Alternatively, the injection multiplication circuitry 145 may be directly coupled to the AFE circuitry 110. An example implementation of the injection multiplication circuitry 145 is illustrated and described in connection with FIG. 2, below.

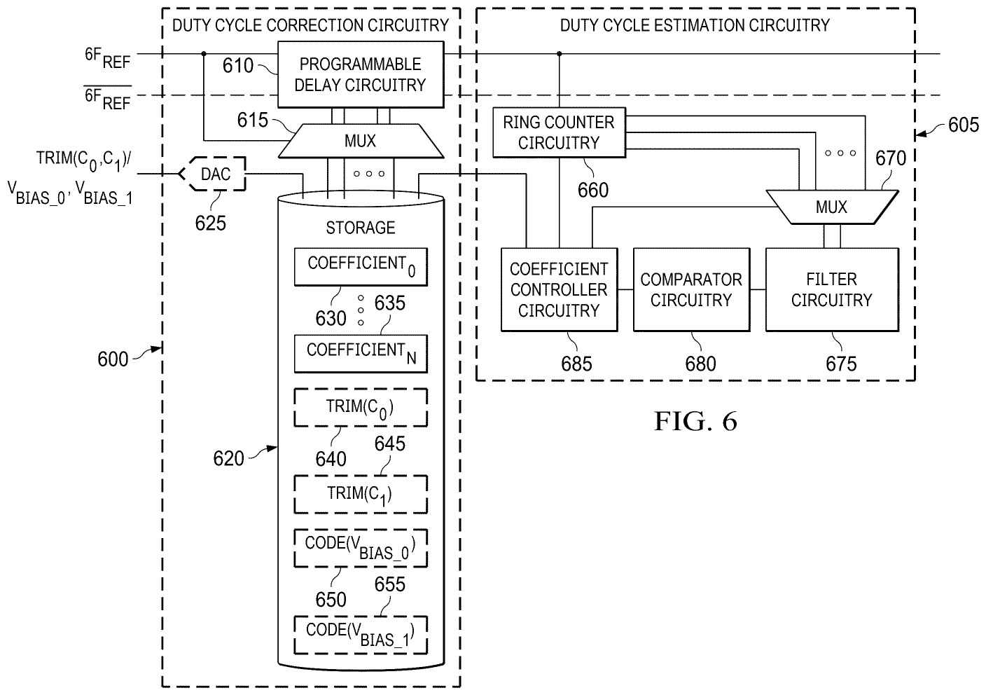

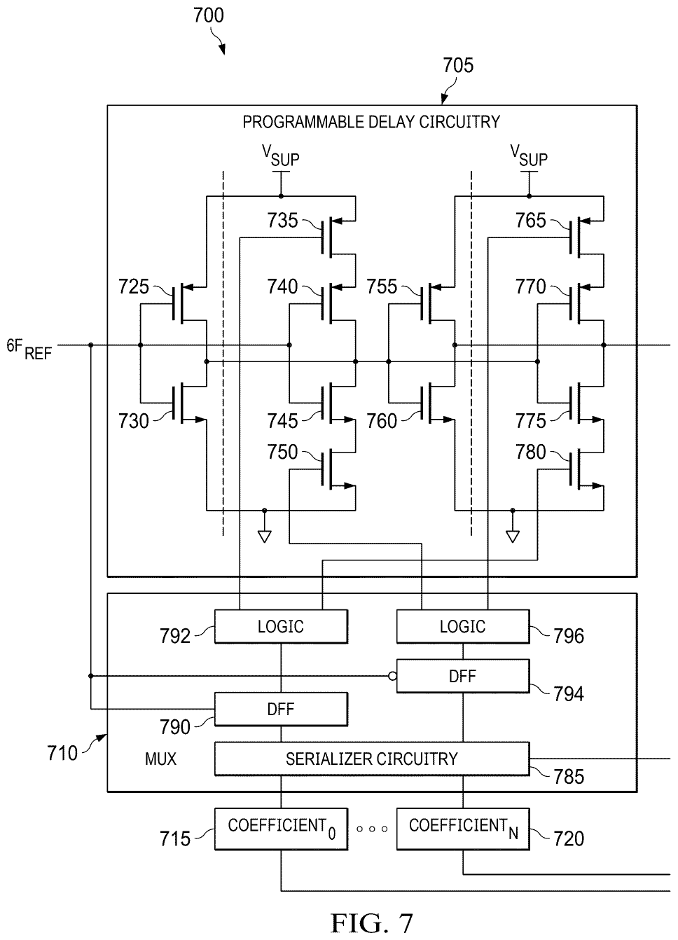

The duty cycle correction circuitry 150 has a first terminal, a second terminal, a third terminal, a fourth terminal, and a fifth terminal. The first and second terminals of the duty cycle correction circuitry 150 are coupled to the injection multiplication circuitry 145. The third terminal of the duty cycle correction circuitry 150 is coupled to the AFE circuitry 110 and the duty cycle estimation circuitry 155. The fourth and fifth terminals of the duty cycle correction circuitry 150 are coupled to the duty cycle estimation circuitry 155. An example implementation of the duty cycle correction circuitry 150 is illustrated and described in connection with FIGS. 6 and 7.

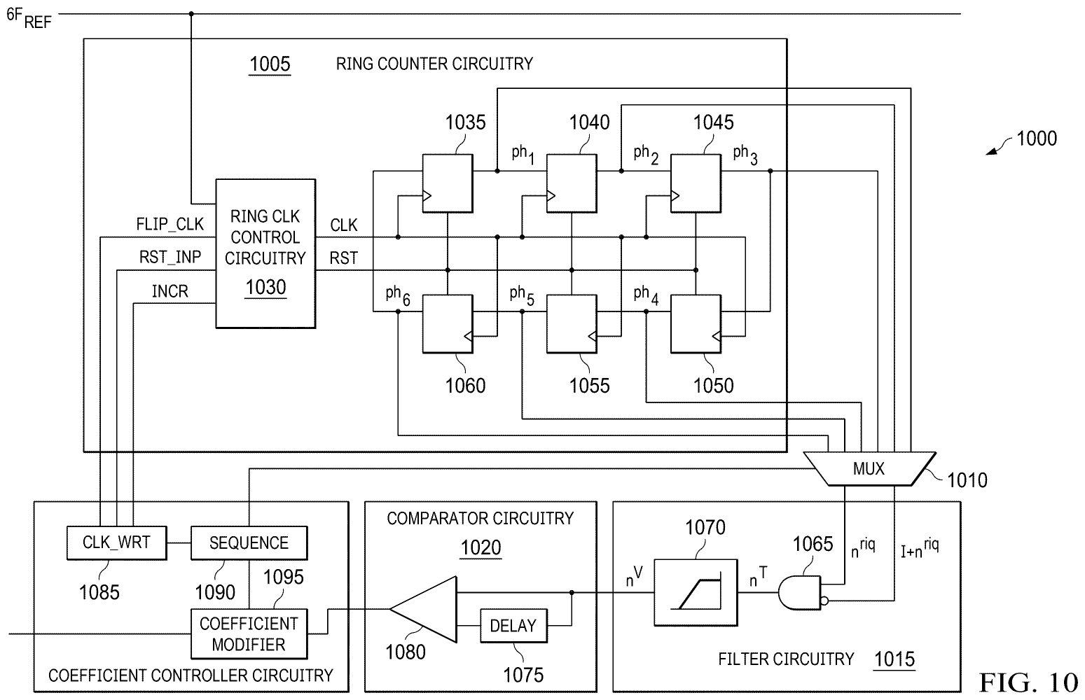

The duty cycle estimation circuitry 155 has a first terminal, a second terminal, and a third terminal. The first terminal of the duty cycle estimation circuitry 155 is coupled to the AFE circuitry 110 and the duty cycle correction circuitry 150. The second and third terminals of the duty cycle estimation circuitry 155 are coupled to the duty cycle correction circuitry 150. An example implementation of the duty cycle estimation circuitry 155 is illustrated and described in connection with FIGS. 6 and 10.

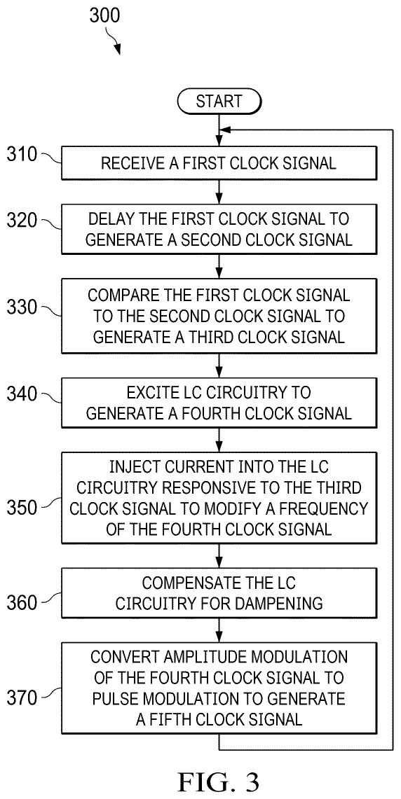

In example operation, the oscillator circuitry 135 generates a first clock signal having a first frequency (F_{REF}). The clock multiplier circuitry 140 receives the first clock signal from the oscillator circuitry 135. The clock multiplier circuitry 140 generates a second clock signal having a second frequency (2F_{REF}) by multiplying the first frequency of the first clock signal. In some examples, the clock multiplier circuitry 140 generates the second clock signal by multiplying the first frequency of the first clock signal by two. Example operations of the clock multiplier circuitry 140 are further described in connection with FIGS. 2 and 3.

The injection multiplication circuitry 145 receives the second clock signal from the clock multiplier circuitry 140. The injection multiplication circuitry 145 generates a third clock signal having a third frequency (6F_{REF}) by multiplying the second frequency of the second clock signal. In some examples, the injection multiplication circuitry 145 generates the third clock signal by multiplying the second frequency of the second clock signal by three. In the example of FIG. 1, the injection multiplication circuitry 145 uses currents of the second clock signal to adjust a resonant frequency, which reduces phase errors. Example operations of the injection multiplication circuitry 145 are further described in connection with FIGS. 2 and 3, below.

In example operations, the duty cycle correction circuitry 150 receives the third clock signal from the injection multiplication circuitry 145. The duty cycle correction circuitry 150 corrects the third clock signal for duty cycle variations between multiples of the first frequency. For example, when the frequency of the third clock signal is six times the frequency of the first clock signal, the duty cycle correction circuitry 150 corrects six duty cycles to be approximately equal to each other. The duty cycle correction circuitry 150 may delay rising edges of the third clock signal to correct each multiple of the first frequency for duty cycle variations. The duty cycle correction circuitry 150 may delay falling edges and of the third clock signal to correct each multiple of the first frequency for duty cycle variations. Example operations of the duty cycle correction circuitry 150 are further described in connection with FIGS. 6, 7, and 8, below. Advantageously, the duty cycle correction circuitry 150 reduces phase errors of the third clock signal.

In example operations, the duty cycle estimation circuitry 155 receives the corrected third clock signal from the duty cycle correction circuitry 150. The duty cycle estimation circuitry 155 determines a duty cycle for each multiple of the first frequency. For example, when the third frequency of the third clock signal is six times the first frequency of the first clock signal, the duty cycle estimation circuitry 155 determines duty cycles for every six cycles of the third clock signal. The duty cycle estimation circuitry 155 generates voltages proportional to the duration of each of the duty cycles. The duty cycle estimation circuitry 155 adjusts the delays of the duty cycle correction circuitry 150 to reduce differences between the voltages of each duty cycle. Example operations of the duty cycle estimation circuitry 155 are further described in connection with FIGS. 6, 10, and 11, below. Advantageously, the duty cycle estimation circuitry 155 determines the delays of the duty cycle correction circuitry 150.

In example operations, the transmitter circuitry 125 receives the corrected third clock signal from the duty cycle correction circuitry 150. The transmitter circuitry 125 transmits a signal using the corrected third clock signal and the antenna 105. In some examples, such as in radar systems, the transmitter circuitry 125 transmits the corrected clock signal. In such examples, the receiver circuitry 130 detects objects responsive to variations in the transmitted signal. Advantageously, reducing the phase errors and harmonics of the clock signal increases the accuracy of the transmitted signal.

FIG. 2 is a schematic diagram of example clock multiplier circuitry 200, which is an example implementation of the clock multiplier circuitry 140 of FIG. 1, and example injection multiplication circuitry 205, which is an example implementation of the injection multiplication circuitry 145. The clock multiplier circuitry 200 of FIG. 2 includes a first example inverter 210, a second example inverter 215, a third example inverter 220, a fourth example inverter 225, and an example logic device 230. The injection multiplication circuitry 205 of FIG. 2 includes example current injection circuitry 235, first example inductor-capacitor (LC) circuitry 240, second example LC circuitry 245, first example current source circuitry 250, a first example transistor 255, a second example transistor 260, and an example amplifier 265. The current injection circuitry 235 of FIG. 2 includes second example current source circuitry 270, a third example transistor 275, and a fourth example transistor 280. The LC circuitry 240 includes a first example capacitor 284 and a first example inductor 288. The LC circuitry 245 includes a second example capacitor 292 and a second example inductor 296.

The clock multiplier circuitry 200 (also referred to as frequency multiplier circuitry) has a first terminal, a second terminal, and a third terminal. The first terminal of the clock multiplier circuitry 200 may be coupled to oscillator circuitry (e.g., oscillator circuitry 135 of FIG. 1), which supplies a clock signal (e.g., CLK(F_{REF})). The second and third terminals of the clock multiplier circuitry 200 are coupled to the injection multiplication circuitry 205.

The injection multiplication circuitry 205 (also referred to as frequency multiplier circuitry) has a first terminal, a second terminal, a third terminal, a fourth terminal, and a fifth terminal. The first and second terminals of the injection multiplication circuitry 205 are coupled to the clock multiplier circuitry 200. The third, fourth, and fifth terminals of the injection multiplication circuitry 205 may be coupled to the duty cycle correction circuitry 150 of FIG. 1. In some examples, the third and fourth terminals of the injection multiplication circuitry 205 are coupled to the AFE circuitry 110 of FIG. 1. In some examples, the fifth terminal of the injection multiplication circuitry 205 is coupled to register circuitry, which supply a first trim code (C₀) and a second trim code (C₁).

The inverter 210 has a first terminal and a second terminal. The first terminal of the inverter 210 is coupled to the logic device 230 and may be coupled to the oscillator circuitry 135. The second terminal of the inverter 210 is coupled to the inverter 215. The inverter 215 has a first terminal and a second terminal. The first terminal of the inverter 215 is coupled to the inverter 210. The second terminal of the inverter 215 is coupled to the inverter 220. The inverter 220 has a first terminal and a second terminal. The first terminal of the inverter 220 is coupled to the inverter 215. The second terminal of the inverter 220 is coupled to the inverter 225. The inverter 225 has a first terminal and a second terminal. The first terminal of the inverter 225 is coupled to the inverter 220. The second terminal of the inverter 225 is coupled to the logic device 230.

In the example of FIG. 2, the inverters 210, 215, 220, 225 have a propagation delay. The inverters 210, 215, 220, 225 are structured as delay circuitry, which delays a clock signal from the oscillator circuitry 135. In some examples, the clock multiplier circuitry 200 may be modified to remove or replace the inverters 210, 215, 220, 225 with alternative delay circuitry.

The logic device 230 has a first terminal, a second terminal, a third terminal, and a fourth terminal. The first terminal of the logic device 230 is coupled to the inverter 210 and may be coupled to the oscillator circuitry 135, which supplies the clock signal. The second terminal of the logic device 230 is coupled to the inverter 225. The third and fourth terminals of the logic device 230 are coupled to the injection multiplication circuitry 205. In the example of FIG. 2, the logic device 230 is an exclusive OR (XOR) gate. In other examples, the clock multiplier circuitry 200 may be modified to implement another type of combinational logic. In the example of FIG. 2, the logic device 230 has a differential output coupled to the injection multiplication circuitry 205. Alternatively, the clock multiplier circuitry 200 may be modified to have the logic device 230 have a single ended output. In such examples, the clock multiplier circuitry 200 may further include single ended to differential converter circuitry.

The current injection circuitry 235 has a first terminal, a second terminal, a third terminal, and a fourth terminal. The first and second terminals of the current injection circuitry 235 are coupled to the clock multiplier circuitry 200. The third terminal of the current injection circuitry 235 is coupled to the LC circuitry 245, the transistors 255, 260, and the amplifier 265. The fourth terminal of the current injection circuitry 235 is coupled to the LC circuitry 240, the transistors 255, 260, and the amplifier 265.

The LC circuitry 240 (e.g., also referred to as LC tank circuitry) has a first terminal and a second terminal. The first terminal of the LC circuitry 240 is coupled to the current injection circuitry 235, the transistors 255, 260, and the amplifier 265. The second terminal of the LC circuitry 240 is coupled to a common terminal, which supplies a common potential (e.g., ground).

The LC circuitry 245 has a first terminal and a second terminal. The first terminal of the LC circuitry 245 is coupled to the current injection circuitry 235, the transistors 255, 260, and the amplifier 265. The second terminal of the LC circuitry 245 is coupled to the common terminal, which supplies the common potential.

The current source circuitry 250 has a first terminal and a second terminal. The first terminal of the current source circuitry 250 is coupled to a supply terminal, which supplies a supply voltage (V_{SUP}). The second terminal of the current source circuitry 250 is coupled to the transistors 255, 260.

The transistor 255 has a first terminal, a second terminal, and a control terminal. The first terminal of the transistor 255 is coupled to the current source circuitry 250 and the transistor 260. The second terminal of the transistor 255 is coupled to the current injection circuitry 235, the LC circuitry 240, the transistor 260, and the amplifier 265. The control terminal of the transistor 255 is coupled to the current injection circuitry 235, the LC circuitry 245, the transistor 260, and the amplifier 265. In the example of FIG. 2, the transistor 255 is an n-channel metal-oxide semiconductor field-effect transistor (MOSFET). Alternatively, with slight modifications the transistor 255 may be an n-channel junction field effect transistor (JFET), an n-channel field-effect transistor (FET), an n-channel insulated-gate bipolar transistor (IGBT), an NPN bipolar junction transistor (BJT) or, with slight modifications, a p-type equivalent device.

The transistor 260 has a first terminal, a second terminal, and a control terminal. The first terminal of the transistor 260 is coupled to the current source circuitry 250 and the transistor 255. The second terminal of the transistor 260 is coupled to the current injection circuitry 235, the LC circuitry 245, the transistor 255, and the amplifier 265. The control terminal of the transistor 260 is coupled to the current injection circuitry 235, the LC circuitry 240, the transistor 255, and the amplifier 265. In the example of FIG. 2, the transistor 260 is an n-channel MOSFET. Alternatively, with slight modifications the transistor 260 may be an n-channel JFET, an n-channel FET, an n-channel IGBT, an NPN BJT or, with slight modifications, a p-type equivalent device.

The amplifier 265 has a first terminal, a second terminal, a third terminal, and a fourth terminal. The first terminal of the amplifier 265 is coupled to the current injection circuitry 235, the LC circuitry 245, and the transistors 255, 260. The second terminal of the amplifier 265 is coupled to the current injection circuitry 235, the LC circuitry 240, and the transistors 255, 260. The third and fourth terminals of the amplifier 265 may be coupled to the duty cycle correction circuitry 150. Alternatively, the third and fourth terminals of the amplifier 265 may be directly coupled to the AFE circuitry 110.

The current source circuitry 270 has a first terminal and a second terminal. The first terminal of the current source circuitry 270 is coupled to the supply terminal, which supplies the supply voltage. The second terminal of the current source circuitry 270 is coupled to the transistors 275, 280.

The transistor 275 has a first terminal, a second terminal, and a control terminal. The first terminal of the transistor 275 is coupled to the current source circuitry 270 and the transistor 280. The second terminal of the transistor 275 is coupled to the LC circuitry 245, the transistors 255, 260, and the amplifier 265. The control terminal of the transistor 275 is coupled to the clock multiplier circuitry 200. In the example of FIG. 2, the transistor 275 is an n-channel MOSFET. Alternatively, with slight modifications the transistor 275 may be an n-channel JFET, an n-channel FET, an n-channel IGBT, an NPN BJT or, with slight modifications, a p-type equivalent device.

The transistor 280 has a first terminal, a second terminal, and a control terminal. The first terminal of the transistor 280 is coupled to the current source circuitry 270 and the transistor 275. The second terminal of the transistor 280 is coupled to the LC circuitry 240, the transistors 255, 260, and the amplifier 265. The control terminal of the transistor 280 is coupled to the clock multiplier circuitry 200. In the example of FIG. 2, the transistor 280 is an n-channel MOSFET. Alternatively, with slight modifications the transistor 280 may be an n-channel JFET, an n-channel FET, an n-channel IGBT, an NPN BJT or, with slight modifications, a p-type equivalent device.

The capacitor 284 has a first terminal and a second terminal. The first terminal of the capacitor 284 is coupled to the current injection circuitry 235, the transistors 255, 260, the amplifier 265, and the inductor 288. The second terminal of the capacitor 284 is coupled to the common terminal, which supplies the common potential. The capacitor 284 has a capacitance. In some examples, the capacitor 284 has trim terminals coupled to the duty cycle correction circuitry 150. In such examples, the capacitance of the capacitor 284 is set by a first trim value (TRIM(C₀)) at the trim terminals. Also in some examples, the capacitor 284 has a bias terminal coupled to the duty cycle correction circuitry 150. In such examples, the capacitor 284 may be referred to as a varactor, which has a capacitance that varies with a voltage across the capacitor 284. Also, when the capacitor 284 is a varactor, the duty cycle correction circuitry 150 sets the bias terminal of the capacitor 284 to a first bias voltage (V_{BIAS_0}) to tune a resonant frequency of the LC circuitry 245. Example operations to set the trim code and the bias voltage of the capacitor 284 are further described below.

The inductor 288 has a first terminal and a second terminal. The first terminal of the inductor 288 is coupled to the current injection circuitry 235, the transistors 255, 260, the amplifier 265, and the capacitor 284. The second terminal of the inductor 288 is coupled to the common terminal, which supplies the common potential. The inductor 288 has an inductance.

In the example of FIG. 2, the capacitor 284 and the inductor 288 are structured as an LC oscillator (e.g., also referred to as an LC tank) having a resonant frequency (f₀). The resonant frequency defines a frequency of an oscillation of charge between the capacitor 284 and the inductor 288. The resonant frequency is proportional to the capacitance of the capacitor 284 and the inductance of the inductor 288. The resonant frequency of the LC oscillator of the capacitor 284 and the inductor 288 may be determined using Equation (1), below. Advantageously, adjusting the trim value of the capacitor 284 allows the duty cycle correction circuitry 150 to adjust the resonant frequency of the LC circuitry 240. Advantageously, adjusting the bias voltage of the capacitor 284 allows the duty cycle correction circuitry 150 to adjust the resonant frequency of the LC circuitry 240.

$${f}_{0} = \frac{1}{2 π \sqrt{L C}} ; \qquad Equation ( 1 )$$

The capacitor 292 has a first terminal and a second terminal. The first terminal of the capacitor 292 is coupled to the current injection circuitry 235, the transistors 255, 260, the amplifier 265, and the inductor 296. The second terminal of the capacitor 292 is coupled to the common terminal, which supplies the common potential. In some examples, the capacitor 292 has trim terminals coupled to the duty cycle correction circuitry 150. In such examples, the capacitance of the capacitor 292 is set by a second trim value (TRIM(C₁)) at the trim terminals. In some examples, the capacitor 292 has a bias terminal coupled to the duty cycle correction circuitry 150. In such examples, the capacitor 292 may be referred to as a varactor, which has a capacitance that varies with a voltage across the capacitor 292. Also, when the capacitor 292 is a varactor, the duty cycle correction circuitry 150 sets the bias terminal of the capacitor 292 to a second bias voltage (V_{BIAS_1}) to tune the LC circuitry 245. Example operations to set the trim code and the bias voltage of the capacitor 292 are further described below.

The inductor 296 has a first terminal and a second terminal. The first terminal of the inductor 296 is coupled to the current injection circuitry 235, the transistors 255, 260, the amplifier 265, and the capacitor 292. The second terminal of the inductor 296 is coupled to the common terminal, which supplies the common potential. The inductor 296 has an inductance.

In the example of FIG. 2, the capacitor 292 and the inductor 296 are structured as an LC oscillator having a resonant frequency (f₀). The resonant frequency defines a frequency of an oscillation of charge between the capacitor 292 and the inductor 296. The resonant frequency is proportional to the capacitance of the capacitor 292 and the inductance of the inductor 296. The resonant frequency of the LC oscillator of the capacitor 292 and the inductor 296 may be determined using Equation (1), above. Advantageously, adjusting the trim value of the capacitor 292 allows the duty cycle correction circuitry 150 to adjust the resonant frequency of the LC circuitry 245. Advantageously, adjusting the bias voltage of the capacitor 284 allows the duty cycle correction circuitry 150 to adjust the resonant frequency of the LC circuitry 240.

FIG. 3 is a flowchart representative of example operations 300 that may be executed, instantiated, or performed to implement the clock multiplier circuitry 140, 200 of FIGS. 1 and 2 and the injection multiplication circuitry 145, 205 of FIGS. 1 and 2. In the example of FIG. 3, the operations 300 begin at Block 310, at which the clock multiplier circuitry 140, 200 receives a first clock signal. (Block 310). In some examples, the inverter 210 of FIG. 2 and the logic device 230 of FIG. 2 receive the clock signal from the oscillator circuitry 135 of FIG. 1.

The clock multiplier circuitry 140, 200 delays the first clock signal to generate a second clock signal. (Block 320). In some examples, the inverters 210, 215, 220, 225 of FIG. 2 have a propagation delay. In such examples, the inverters 210, 215, 220, 225 generate the second clock signal by delaying the first clock signal from the oscillator circuitry 135 by the duration of the propagation delay.

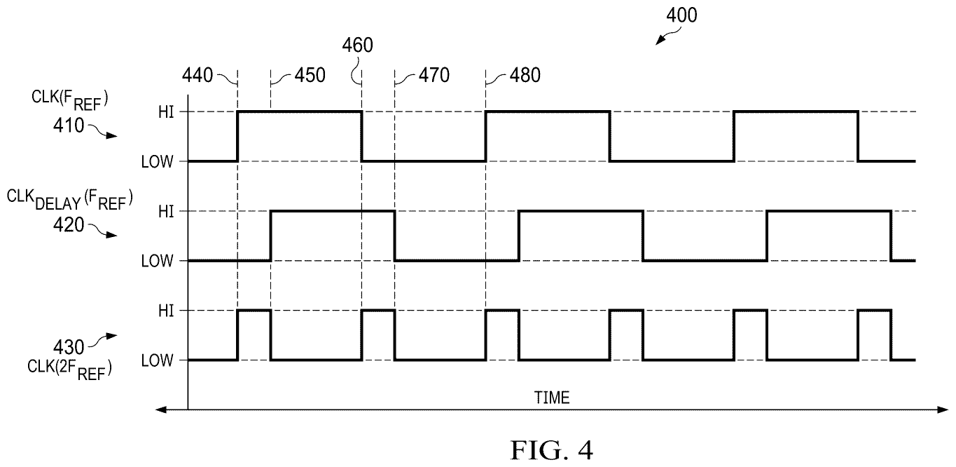

The clock multiplier circuitry 140, 200 compares the first clock signal to the second clock signal to generate a third clock signal. (Block 330). In some examples, the logic device 230 performs an XOR operation between the first clock signal from the oscillator circuitry 135 and the second clock signal from the inverter 225 to generate the third clock signal. An example of the first, second, and third clock signals are illustrated and described in connection with FIG. 4, below. Advantageously, the third clock signal has a frequency that is approximately equal to a multiple of the frequency of the first clock signal from the oscillator circuitry 135.

The injection multiplication circuitry 145, 205 excites LC circuitry to generate a fourth clock signal. (Block 340). In some examples, the current source circuitry 250 of FIG. 2 and the transistors 255, 260 of FIG. 2 supplies current to the LC circuitry 240, 245 of FIG. 2. In such examples, the current excites the LC circuitry 240, 245 by charging the inductors 288, 296 of FIG. 2. Once excited, the inductors 288, 296 and the capacitors 284, 292 of FIG. 2 pass charge from the current to generate the fourth clock signal as a sinusoidal signal.

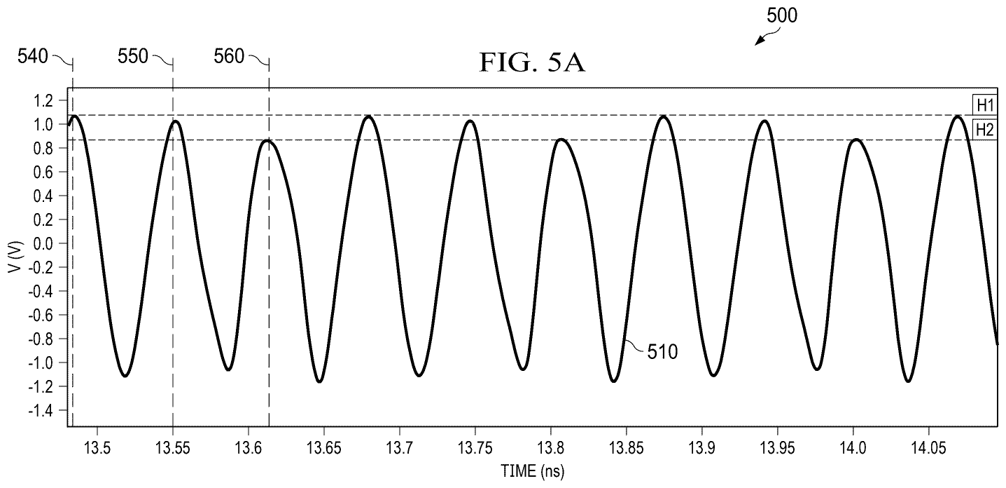

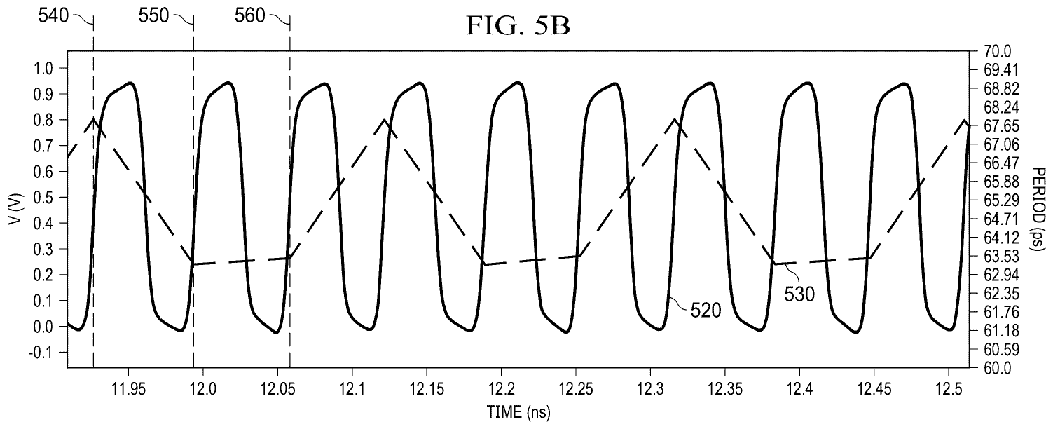

The injection multiplication circuitry 145, 205 injects current into the LC circuitry responsive to the third clock signal to modify a frequency of the fourth clock signal. (Block 350). In some examples, the current injection circuitry 235 of FIG. 2 supplies current to the LC circuitry 240, 245 responsive to the third clock signal from the clock multiplier circuitry 140, 200. In such example operations, the current source circuitry 270 of FIG. 2 supplies current to the LC circuitry 240, 245 responsive to amplitudes of the third clock signal turning on the transistors 275, 280 of FIG. 2. Such an injection of current to the LC circuitry 240, 245 modifies the voltage across the capacitors 284, 292, which modifies the capacitance of the capacitors 284, 292. Advantageously, injecting current into the LC circuitry 240, 245 modifies the resonant frequency of the LC circuitry 240, 245, which changes the frequency of the fourth clock signal. An example of the fourth clock signal is illustrated and described in connection with FIG. 5A, below.

The injection multiplication circuitry 145, 205 compensates the LC circuitry for dampening. (Block 360). In some examples, the LC circuitry 240, 245 loses some charge between the charge and discharge of the capacitors 284, 292 and the inductors 288, 296. Such a loss may be illustrated and described as a parasitic resistance coupled in parallel with the LC circuitry 240, 245. The losses resulting from the parasitic resistance dampens the amplitudes of the fourth clock signal over time. In such examples, the current source circuitry 250 continues to supply current to the LC circuitry 240, 245 to compensate for the losses resulting from the parasitic resistance. For example, when the fourth clock signal has an amplitude greater than a threshold voltage of the transistors 255, 260, the fourth clock signal turns on the transistors 255, 260 and the current source circuitry 250 supplies current to the LC circuitry 240, 245. Advantageously, the current source circuitry 250 and the transistors 255, 260 compensate the LC circuitry 240, 245 for amplitude dampening resulting from parasitic losses.

The injection multiplication circuitry 145, 205 converts amplitude modulation of the fourth clock signal to pulse modulation to generate a fifth clock signal. (Block 370). In some examples, the amplifier 265 generates a fifth clock signal by converting the amplitude modulation of the fourth clock signal to a pulse modulation. In such examples, the amplifier 265 generates the fifth clock signal as a square waveform having a frequency that is approximately, preferably exactly, equal to the frequency of the fourth clock signal. An example of the fifth clock signal is illustrated and described in connection with FIG. 5B, below.

Although example methods are described with reference to the flowchart illustrated in FIG. 3, many other methods of implementing the clock multiplier circuitry 140, 200 or the injection multiplication circuitry 145, 205 may alternatively be used in accordance with this description. For example, the order of execution of the blocks may be changed, and some of the blocks described may be changed, eliminated, or combined. Similarly, additional operations may be included in the manufacturing process before, in between, or after the blocks shown in the illustrated examples.

FIG. 4 is an example timing diagram 400 of example operations of the clock multiplier circuitry 140, 200 of FIGS. 1 and 2. In the example of FIG. 4, the timing diagram 400 includes a first clock signal 410 (CLK(F_{REF})), a second clock signal 420 (CLK_{DELAY}(F_{REF})), and a third clock signal 430 (CLK(2F_{REF})). The clock signal 410 has a first frequency (F_{REF}) and represents a clock signal from the oscillator circuitry 135 of FIG. 1. The clock signal 420 represents a delayed version of the clock signal 410. The inverters 210, 215, 220, 225 of FIG. 2 generate the clock signal 420 by delaying the clock signal 410 by a delay duration, which is proportional to the propagation delay of the inverters 210, 215, 220, 225. The clock signal 430 has a second frequency (2F_{REF}) and represents a clock signal from the logic device 230 of FIG. 2. Advantageously, the second frequency of the clock signal 430 is approximately, preferably exactly, equal to two times the first frequency of the clock signals 410, 420.

At a first time 440, the clock signals 410, 430 have a rising edge. At a second time 450, the clock signal 420 has a rising edge and the clock signal has a falling edge. The duration between the times 440, 450 represents the delay duration of the inverters 210, 215, 220, 225. Advantageously, the propagation delay of the inverters 210, 215, 220, 225 set the pulse width of the clock signal 430.

At a third time 460, the clock signal 410 has a falling edge and the clock signal 430 has a rising edge. At a fourth time 470, the clock signals 420, 430 have a falling edge. The duration between the times 460, 470 is approximately, preferably exactly, equal to the duration between the times 440, 450. At a fifth time 480, the clock signals 410, 430 have a rising edge. Between the times 440, 480, the clock signal 410 has one cycle and the clock signal 430 has multiple cycles. Advantageously, the clock multiplier circuitry 140, 200 generates a clock signal having a frequency that is approximately, preferably exactly, equal to two times the frequency of the clock signal from the oscillator circuitry 135. Advantageously, the clock signal from the clock multiplier circuitry 140, 200 has a pulse width that is approximately, preferably exactly, equal to the pulse width of a clock signal from the injection multiplication circuitry 145, 205 of FIGS. 1 and 2.

FIGS. 5A and 5B are example timing diagrams 500 of example operations of the injection multiplication circuitry 145, 205 of FIGS. 1 and 2. In the example of FIGS. 5A and 5B, the timing diagrams 500 include an example amplitude modulation (AM) clock signal 510, an example pulse modulation (PM) clock signal 520, and an example period signal 530. The AM clock signal 510 represents a clock signal resulting from the oscillation of the LC circuitry 240, 245 of FIG. 2, or more generally, the injection multiplication circuitry 145, 205. The AM clock signal 510 represents the use of subharmonic injection in generating a higher frequency clock signal. Subharmonic injection is a process of using the current injection circuitry 235 of FIG. 2 to inject current to the LC circuitry 240, 245 at a frequency that is less than the frequency of the AM clock signal 510. In the example of FIG. 5A, the frequency of the AM clock signal 510 is approximately, preferably exactly, a multiple of the frequency of the clock signal of the clock signal 430 of FIG. 4. The PM clock signal 520 represents a clock signal resulting from the AM-to-PM conversion of the amplifier 265 of FIG. 2. The period signal 530 represents the period of the PM clock signal 520.

At a first time 540, an amplitude of the AM clock signal 510 has a first value and the amplitude of the period signal 530 represents the PM clock signal 520 having a first period. At a second time 550, the amplitude of the AM clock signal 510 has a second value and the amplitude of the period signal 530 represents the PM clock signal 520 having a second period. At a third time 560, the amplitude of the AM clock signal 510 has a third value and the amplitude of the period signal 530 represents the PM clock signal 520 having a third period.

At the first time 540, the current injection circuitry 235 of FIG. 2 receives a pulse of the clock signal from the clock multiplier circuitry 140, 200 of FIGS. 1 and 2 (e.g., the clock signal 430 of FIG. 4). For example, the amplitude of the AM clock signal 510 has the first value responsive to the pulse of the clock signal 430 between the times 440, 450 of FIG. 4. In such an example, the current injection circuitry 235 injects current into the LC circuitry 240, 245 responsive to the pulse of the clock signal 430.

Between the times 540, 560, the current injection circuitry 235 corresponds to the duration between times 450, 460 of FIG. 4. During the times 540, 560, the amplitude of the AM clock signal 510 decreases responsive to losses of the LC circuitry 240, 245 and the resonant frequency of the LC circuitry 240, 245 returning to a fundamental resonant frequency. Also, between the times 540, 560, the period of the PM clock signal 520 changes from the time 540 responsive to decreases in the amplitudes of the AM clock signal 510. Advantageously, the duty cycle correction circuitry 150 may reduce variations in the period signal 530 by adjusting the rising and falling edges of the PM clock signal 520.

FIG. 6 is a block diagram of example duty cycle correction circuitry 600, which is an example of the duty cycle correction circuitry 150 of FIG. 1, and example duty cycle estimation circuitry 605, which is an example of the duty cycle estimation circuitry 155 of FIG. 1. The duty cycle correction circuitry 600 of FIG. 6 includes example programmable delay circuitry 610, example multiplexer circuitry 615, an example storage 620, and an example digital-to-analog converter (DAC) 625. The storage 620 of FIG. 6 further includes a first example coefficient 630, a second example coefficient 635, a first example trim value 640, a second example trim value 645, a first example DAC code 650, and a second example DAC code 655. The duty cycle estimation circuitry 605 of FIG. 6 includes example ring counter circuitry 660, example multiplexer circuitry 670, example filter circuitry 675, example comparator circuitry 680, and example coefficient controller circuitry 685.

The duty cycle correction circuitry 600 has a first terminal, a second terminal, a third terminal, a fourth terminal, a fifth terminal, a sixth terminal, and a seventh terminal. The first and second terminals of the duty cycle correction circuitry 600 may be coupled to the injection multiplication circuitry 145, 205 of FIGS. 1 and 2. The third and fourth terminals of the duty cycle correction circuitry 600 are coupled to the duty cycle estimation circuitry 605 and may be coupled to the AFE circuitry 110 of FIG. 1. The fifth and sixth terminals of the duty cycle correction circuitry 600 are coupled to the duty cycle estimation circuitry 605. The seventh terminal of the duty cycle correction circuitry 600 may be coupled to the LC circuitry 240, 245 of FIG. 2, or more generally, the injection multiplication circuitry 145, 205. In some examples, the duty cycle correction circuitry 600 has a plurality of terminals coupled to the capacitors 284, 292 of FIG. 2. Another example of the duty cycle correction circuitry 600 is illustrated and described in connection with FIG. 7, below.

The duty cycle estimation circuitry 605 has a first terminal, a second terminal, a third terminal, and a fourth terminal. The first and second terminals of the duty cycle estimation circuitry 605 are coupled to the duty cycle correction circuitry 600 and may be coupled to the AFE circuitry 110. The third and fourth terminals of the duty cycle estimation circuitry 605 are coupled to the duty cycle correction circuitry 600. In some examples, the duty cycle estimation circuitry 605 is communicatively coupled to the duty cycle correction circuitry 600. Another example of the duty cycle estimation circuitry 605 is illustrated and described in connection with FIG. 10, below.

The programmable delay circuitry 610 has a first terminal, second terminal, third terminal, a fourth terminal, a fifth terminal, sixth terminal, a seventh terminal, and an eighth terminal. The first and second terminals of the programmable delay circuitry 610 may be coupled to the injection multiplication circuitry 145, 205. The third and fourth terminals of the programmable delay circuitry 610 are coupled to the duty cycle estimation circuitry 605 and may be coupled to the AFE circuitry 110. The fifth, sixth, seventh, and eighth terminals of the programmable delay circuitry 610 are coupled to the multiplexer circuitry 615. In some examples, the programmable delay circuitry 610 may have any number of terminals coupled to the multiplexer circuitry 615. An example implementation of the programmable delay circuitry 610 is illustrated and described in connection with FIG. 7, below.

The multiplexer circuitry 615 has a first terminal, a second terminal, a third terminal, a fourth terminal, a fifth terminal, a sixth terminal, a seventh terminal, an eighth terminal, and a ninth terminal. The first, second, third, and fourth terminals of the multiplexer circuitry 615 are coupled to the programmable delay circuitry 610. In some examples, the multiplexer circuitry 615 may have any number of terminals coupled to the programmable delay circuitry 610. The fifth terminal of the multiplexer circuitry 615 is coupled to the duty cycle estimation circuitry 605. The sixth, seventh, and eighth terminals of the multiplexer circuitry 615 are coupled to the storage 620. In some examples, the multiplexer circuitry 615 may have any number of terminals coupled to the storage 620 or the contents of the storage, such as the coefficients 630, 635. The ninth terminal of the multiplexer circuitry 615 is coupled to the programmable delay circuitry 610 and may be coupled to the injection multiplication circuitry 145, 205. An example implementation of the multiplexer circuitry 615 is illustrated and described in connection with FIG. 7, below.

The storage 620 has a first terminal, a second terminal, a third terminal, a fourth terminal, and a fifth terminal. The first, second, and third terminals of the storage 620 are coupled to the multiplexer circuitry 615. In some examples, the storage 620 may have any number of terminals coupled to the multiplexer circuitry 615. The fourth terminal of the storage 620 is coupled to the duty cycle estimation circuitry 605. In some examples, the storage 620 may have a plurality of terminals coupled to the duty cycle estimation circuitry 605. The storage 620 is communicatively coupled to the duty cycle estimation circuitry 605. The fifth terminal of the storage 620 is coupled to the DAC 625. In some examples, the storage has a plurality of terminals coupled to the DAC 625. Also, the storage 620 may have additional terminals coupled to another DAC. In the example of FIG. 6, the storage 620 is non-volatile memory. In other examples, the storage 620 may be one or more alternative forms of memory, such as a plurality of registers that, when loaded with data, store one or more components of the storage 620. Such an example is illustrated and described in connection with FIG. 7, below.

The DAC 625 has a first terminal and a second terminal. The first terminal of the DAC 625 is coupled to the storage 620. In some examples, the DAC 625 has a plurality of terminals coupled to the storage 620. The second terminal of the DAC 625 may be coupled to the capacitors 284, 292, or more generally, the LC circuitry 240, 245, or even more generally the injection multiplication circuitry 145, 205.

The coefficients 630, 635 are portions of memory that store delay values, which represent a delay of the programmable delay circuitry 610. In some examples, each of the coefficients 630, 635 correspond to one of a rising edge or a falling edge of a cycle of the clock signal from the injection multiplication circuitry 145, 205. In such examples, the storage 620 may include a plurality of coefficients corresponding to each rising and falling edge of cycles of a clock signal. For example, when the injection multiplication circuitry 145, 205 multiplies the frequency of the clock signal from the clock multiplier circuitry 200 by three, the storage 620 includes six coefficients. The trim values 640, 645 are portions of memory that, when supplied, set the capacitance of the capacitors 284, 292. The DAC codes 650, 655 are portions of memory that, when supplied to the DAC 625, set the bias voltage of the capacitors 284, 292.

The ring counter circuitry 660 has a first terminal, a second terminal, a third terminal, a fourth terminal, and a fifth terminal. The first terminal of the ring counter circuitry 660 is coupled to the duty cycle correction circuitry 600 and may be coupled to the AFE circuitry 110. The second terminal of the ring counter circuitry 660 is coupled to the duty cycle correction circuitry 600. The third, fourth, and fifth terminals of the ring counter circuitry 660 are coupled to the multiplexer circuitry 670. Alternatively, the ring counter circuitry 660 may have any plurality of terminals coupled to the multiplexer circuitry 670. An example implementation of the ring counter circuitry 660 is illustrated and described in connection with FIG. 10, below.

The multiplexer circuitry 670 has a first terminal, a second terminal, a third terminal, a fourth terminal, a fifth terminal, and a sixth terminal. The first, second, and third terminals of the multiplexer circuitry 670 are coupled to the ring counter circuitry 660. Alternatively, the multiplexer circuitry 670 may have any number of terminals coupled to the ring counter circuitry 660. The fourth and fifth terminals of the multiplexer circuitry 670 are coupled to the filter circuitry 675. The sixth terminal of the multiplexer circuitry 670 is coupled to the coefficient controller circuitry 685.

The filter circuitry 675 has a first terminal, a second terminal, and a third terminal. The first and second terminals of the filter circuitry 675 are coupled to the multiplexer circuitry 670. The third terminal of the filter circuitry 675 is coupled to the comparator circuitry 680. An example implementation of the filter circuitry 675 is illustrated and described in connection with FIG. 10, below.

The comparator circuitry 680 has a first terminal and a second terminal. The first terminal of the comparator circuitry 680 is coupled to the filter circuitry 675. The second terminal of the comparator circuitry 680 is coupled to the coefficient controller circuitry 685. An example implementation of the comparator circuitry 680 is illustrated and described in connection with FIG. 10, below.

The coefficient controller circuitry 685 has a first terminal, a second terminal, a third terminal, and a fourth terminal. The first terminal of the coefficient controller circuitry 685 is coupled to the duty cycle correction circuitry 600. In some examples, the coefficient controller circuitry 685 is communicatively coupled with the duty cycle correction circuitry 600. Alternatively, the coefficient controller circuitry 685 may have a plurality of terminals coupled to the duty cycle correction circuitry 600. The second terminal of the coefficient controller circuitry 685 is coupled to the ring counter circuitry 660. The third terminal of the coefficient controller circuitry 685 is coupled to the multiplexer circuitry 670. The fourth terminal of the coefficient controller circuitry 685 is coupled to the comparator circuitry 680. An example implementation of the coefficient controller circuitry 685 is illustrated and described in connection with FIG. 10, below.

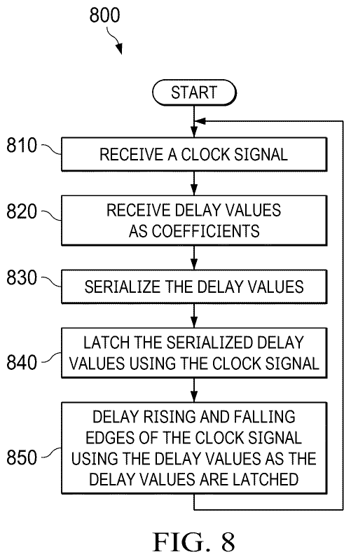

In example operation, the duty cycle correction circuitry 600 receives a clock signal from the injection multiplication circuitry 145, 205 of FIGS. 1 and 2. The duty cycle correction circuitry 600 adjusts rising and falling edges of the clock signal responsive to delay values of the coefficients 630, 635. The multiplexer circuitry 615 sets the delay values of the programmable delay circuitry 610 by serializing the coefficients 630, 635. Advantageously, the duty cycle correction circuitry 600 reduces variations in duty cycles of the clock signal by adjusting rising and falling edges. Example operations of the duty cycle correction circuitry 600 are further described and illustrated in connection with FIGS. 7 and 8, below.

In some example operations, the duty cycle correction circuitry 600 includes the DAC 625. The DAC 625 generates analog voltages responsive to the DAC codes 650, 655. The DAC 625 modifies the resonant frequency of the LC circuitry 240, 245 of FIG. 2 by biasing the capacitors 284, 292 of FIG. 2 by the analog voltages, which modifies the capacitance of the capacitors 284, 292. In such example operations, the duty cycle correction circuitry 600 may further supply the trim values 640, 645 to the capacitors 284, 292. The trim values 640, 645 allow the duty cycle correction circuitry 600 relatively more precise control over the capacitance of the capacitors 284, 292.

Advantageously, the trim values 640, 645 and the DAC codes 650, 655 allow the duty cycle correction circuitry 600 to adjust the frequency of the clock signal from the injection multiplication circuitry 205. In some examples, duty cycle correction circuitry 600 may include circuitry to determine values of the trim values 640, 645 and the DAC codes 650, 655 to set the frequency of the clock signal from the injection multiplication circuitry 145, 205 approximately, preferably exactly, equal to a target frequency. In other examples, the values of the trim value 640, 645 and the DAC codes 650, 655 are set during manufacturing or as part of a calibration process to set the frequency of the clock signal from the injection multiplication circuitry 145, 205 approximately, preferably exactly, equal to a target frequency.

In example operation, the duty cycle estimation circuitry 605 receives a corrected clock signal from the duty cycle correction circuitry 150, 600 of FIGS. 1 and 6. The ring counter circuitry 660 generates a clock signal for each multiple of the frequency of the clock signal from the oscillator circuitry 135. The filter circuitry 675 generates voltages that correspond to each duty cycle of the clock signals. The comparator circuitry 680 compares the voltages to determine variations between duty cycles. The coefficient controller circuitry 685 adjusts the coefficients 630, 635 to correct for variations in the duty cycles. Advantageously, the duty cycle estimation circuitry 605 adjusts delays of the duty cycle correction circuitry 600 to reduce variations between rising and falling edges of the clock signal, which reduces phase error.

FIG. 7 is a schematic diagram of example duty cycle correction circuitry 700, which is another example of the duty cycle correction circuitry 150, 600 of FIGS. 1 and 6. In the example of FIG. 7, the duty cycle correction circuitry 700 includes programmable delay circuitry 705, multiplexer circuitry 710, a first coefficient 715, and a second coefficient 720. The programmable delay circuitry 705 of FIG. 7 further includes a first example transistor 725, a second example transistor 730, a third example transistor 735, a fourth example transistor 740, a fifth example transistor 745, a sixth example transistor 750, a seventh example transistor 755, an eighth example transistor 760, a ninth example transistor 765, a tenth example transistor 770, an eleventh example transistor 775, and a twelfth example transistor 780. The multiplexer circuitry 710 of FIG. 7 further includes example serializer circuitry 785, a first example flip-flop 790, first example logic circuitry 792, a second example flip-flop 794, and second example logic circuitry 796.

The programmable delay circuitry 705 has a first terminal, a second terminal, a third terminal, a fourth terminal, a fifth terminal, and a sixth terminal. The first terminal of the programmable delay circuitry 705 is coupled to the multiplexer circuitry 710 and may be coupled to the injection multiplication circuitry 145, 205 of FIGS. 1 and 2. The second terminal of the programmable delay circuitry 705 may be coupled to one or both of the AFE circuitry 110 of FIG. 1 and the duty cycle estimation circuitry 155, 605 of FIGS. 1 and 6. The third, fourth, fifth, and sixth terminals of the programmable delay circuitry 705 are coupled to the multiplexer circuitry 710. The programmable delay circuitry 705 is an example of the programmable delay circuitry 610 of FIG. 6.

The multiplexer circuitry 710 has a first terminal, a second terminal, a third terminal, a fourth terminal, a fifth terminal, a sixth terminal, a seventh terminal, and an eighth terminal. The first, second, third, fourth and fifth terminals of the multiplexer circuitry 710 are coupled to the programmable delay circuitry 705. The fifth terminal of the multiplexer circuitry 710 may further be coupled to the injection multiplication circuitry 145, 205. The sixth terminal of the multiplexer circuitry 710 is coupled to the coefficient 715. The seventh terminal of the multiplexer circuitry 710 is coupled to the coefficient 720. The eighth terminal of the multiplexer circuitry 710 may be coupled to the duty cycle estimation circuitry 155, 605. The multiplexer circuitry 710 is an example of the multiplexer circuitry 615 of FIG. 6.

The coefficient 715 has a first terminal and a second terminal. The first terminal of the coefficient 715 is coupled to the multiplexer circuitry 710. The second terminal of the coefficient 715 may be coupled to the duty cycle estimation circuitry 155, 605. The coefficient 715 is an example of the coefficient 630 of FIG. 6. In the example of FIG. 7, the coefficient 715 is structured as memory, such as a register. In such examples, the value of the memory is the coefficient 715. In other examples, such as FIG. 6, the coefficient 715 is a portion of memory circuitry, which stores a plurality of values.

The coefficient 720 has a first terminal and a second terminal. The first terminal of the coefficient 720 is coupled to the multiplexer circuitry 710. The second terminal of the coefficient 720 may be coupled to the duty cycle estimation circuitry 155, 605. The coefficient 720 is an example of the coefficient 635 of FIG. 6. In the example of FIG. 7, the coefficient 720 is structured as memory, such as a register. In such examples, the value of the memory is the coefficient 720. In other examples, such as FIG. 6, the coefficient 720 is a portion of memory circuitry, which stores a plurality of values.

The transistor 725 has a first terminal, a second terminal, and a control terminal. The first terminal of the transistor 725 is coupled to a supply terminal, which supplies a supply voltage (V_{SUP}). The second terminal of the transistor 725 is coupled to the transistors 730, 740, 745, 755, 760, 770, 775. The control terminal of the transistor 725 is coupled to the multiplexer circuitry 710, the transistors 730, 740, 745, and may be coupled to the injection multiplication circuitry 145, 205. In the example of FIG. 7, the transistor 725 is an n-channel MOSFET. Alternatively, with slight modifications the transistor 725 may be an n-channel JFET, an n-channel FET, an n-channel IGBT, an NPN BJT or, with slight modifications, a p-type equivalent device.

The transistor 730 has a first terminal, a second terminal, and a control terminal. The first terminal of the transistor 730 is coupled to the transistors 725, 740, 745, 755, 760, 770, 775. The second terminal of the transistor 730 is coupled to a common terminal, which supplies a common potential (e.g., ground). The control terminal of the transistor 730 is coupled to the multiplexer 710, the transistors 725, 740, 745, and may be coupled to the injection multiplication circuitry 145, 205. In the example of FIG. 7, the transistor 730 is a p-channel MOSFET. Alternatively, with slight modifications the transistor 730 may be a p-channel JFET, a p-channel FET, a p-channel IGBT, a PNP BJT or, with slight modifications, an n-type equivalent device.

The transistor 735 has a first terminal, a second terminal, and a control terminal. The first terminal of the transistor 735 is coupled to the supply terminal, which supplies the supply voltage. The second terminal of the transistor 735 is coupled to the transistor 740. The control terminal of the transistor 735 is coupled to the multiplexer circuitry 710. In the example of FIG. 7, the transistor 735 is an n-channel MOSFET. Alternatively, with slight modifications the transistor 735 may be an n-channel JFET, an n-channel FET, an n-channel IGBT, an NPN BJT or, with slight modifications, a p-type equivalent device.

The transistor 740 has a first terminal, a second terminal, and a control terminal. The first terminal of the transistor 740 is coupled to the transistor 735. The second terminal of the transistor 740 is coupled to the transistors 725, 730, 745, 755, 760, 770, 775. The control terminal of the transistor 740 is coupled to the multiplexer circuitry 710, the transistors 725, 730, 740, and may be coupled to the injection multiplication circuitry 145, 205. In the example of FIG. 7, the transistor 740 is an n-channel MOSFET. Alternatively, with slight modifications the transistor 740 may be an n-channel JFET, an n-channel FET, an n-channel IGBT, an NPN BJT or, with slight modifications, a p-type equivalent device.

The transistor 745 has a first terminal, a second terminal, and a control terminal. The first terminal of the transistor 745 is coupled to the transistors 725, 730, 740, 755, 760, 770, 775. The second terminal of the transistor 745 is coupled to the transistor 750. The control terminal of the transistor 745 is coupled to the multiplexer circuitry 710, the transistors 725, 730, 740, and may be coupled to the injection multiplication circuitry 145, 205. In the example of FIG. 7, the transistor 745 is a p-channel MOSFET. Alternatively, with slight modifications the transistor 745 may be a p-channel JFET, a p-channel FET, a p-channel IGBT, a PNP BJT or, with slight modifications, an n-type equivalent device.

The transistor 750 has a first terminal, a second terminal, and a control terminal. The first terminal of the transistor 750 is coupled to the transistor 745. The second terminal of the transistor 750 is coupled to the common terminal, which supplies the common potential. The control terminal of the transistor 750 is coupled to the multiplexer circuitry 710. In the example of FIG. 7, the transistor 750 is a p-channel MOSFET. Alternatively, with slight modifications the transistor 750 may be a p-channel JFET, a p-channel FET, a p-channel IGBT, a PNP BJT or, with slight modifications, an n-type equivalent device.

The transistor 755 has a first terminal, a second terminal, and a control terminal. The first terminal of the transistor 755 is coupled to the supply terminal, which supplies the supply voltage. The second terminal of the transistor 755 is coupled to the transistors 760, 770, 775 and may be coupled to one or both of the AFE circuitry 110 and the duty cycle estimation circuitry 155, 605. The control terminal of the transistor 755 is coupled to the transistors 725, 730, 740, 745, 760, 770, 775. In the example of FIG. 7, the transistor 755 is an n-channel MOSFET. Alternatively, with slight modifications the transistor 755 may be an n-channel JFET, an n-channel FET, an n-channel IGBT, an NPN BJT or, with slight modifications, a p-type equivalent device.

The transistor 760 has a first terminal, a second terminal, and a control terminal. The first terminal of the transistor 760 is coupled to the transistors 755, 770, 775 and may be coupled to one or both the AFE circuitry 110 and the duty cycle estimation circuitry 155, 605. The second terminal of the transistor 760 is coupled to the common terminal, which supplies the common potential. The control terminal of the transistor 760 is coupled to the transistors 725, 730, 740, 745, 755, 770, 775. In the example of FIG. 7, the transistor 760 is a p-channel MOSFET. Alternatively, with slight modifications the transistor 760 may be a p-channel JFET, a p-channel FET, a p-channel IGBT, a PNP BJT or, with slight modifications, an n-type equivalent device.

The transistor 765 has a first terminal, a second terminal, and a control terminal. The first terminal of the transistor 765 is coupled to the supply terminal, which supplies the supply voltage. The second terminal of the transistor 765 is coupled to the transistor 770. The control terminal of the transistor 765 is coupled to the multiplexer circuitry 710. In the example of FIG. 7, the transistor 765 is an n-channel MOSFET. Alternatively, with slight modifications the transistor 765 may be an n-channel JFET, an n-channel FET, an n-channel IGBT, an NPN BJT or, with slight modifications, a p-type equivalent device.

The transistor 770 has a first terminal, a second terminal, and a control terminal. The first terminal of the transistor 770 is coupled to the transistor 765. The second terminal of the transistor 770 is coupled to the transistors 755, 760, 775 and may be coupled to one of or both the AFE circuitry 110 and the duty cycle estimation circuitry 155, 605. The control terminal of the transistor 770 is coupled to the transistors 725, 730, 740, 745, 755, 760, 775. In the example of FIG. 7, the transistor 770 is an n-channel MOSFET. Alternatively, with slight modifications the transistor 770 may be an n-channel JFET, an n-channel FET, an n-channel IGBT, an NPN BJT or, with slight modifications, a p-type equivalent device.

The transistor 775 has a first terminal, a second terminal, and a control terminal. The first terminal of the transistor 775 is coupled to the transistors 755, 760, 770 and may be coupled to one of or both the AFE circuitry 110 and the duty cycle estimation circuitry 155, 605. The second terminal of the transistor 775 is coupled to the transistor 780. The control terminal of the transistor 775 is coupled to the transistors 725, 730, 740, 745, 755, 760, 770. In the example of FIG. 7, the transistor 775 is a p-channel MOSFET. Alternatively, with slight modifications the transistor 775 may be a p-channel JFET, a p-channel FET, a p-channel IGBT, a PNP BJT or, with slight modifications, an n-type equivalent device.

The transistor 780 has a first terminal, a second terminal, and a control terminal. The first terminal of the transistor 780 is coupled to the transistor 775. The second terminal of the transistor 780 is coupled to the common terminal, which supplies the common potential. In the example of FIG. 7, the transistor 780 is a p-channel MOSFET. Alternatively, with slight modifications the transistor 780 may be a p-channel JFET, a p-channel FET, a p-channel IGBT, a PNP BJT or, with slight modifications, an n-type equivalent device.

The serializer circuitry 785 has a first terminal, a second terminal, a third terminal, a fourth terminal, and a fifth terminal. The first terminal of the serializer circuitry 785 is coupled to the coefficient 715. The second terminal of the serializer circuitry 785 is coupled to the coefficient 720. The third terminal of the serializer circuitry 785 is coupled to the flip-flop 790. The fourth terminal of the serializer circuitry 785 is coupled to the flip-flop 794. The fifth terminal of the serializer circuitry 785 may be coupled to the duty cycle estimation circuitry 155, 605. Alternatively, the serializer circuitry 785 may have any number of terminals coupled to any number of coefficients.

The flip-flop 790 has a first terminal, a second terminal, and a third terminal. The first terminal of the flip-flop 790 is coupled to the serializer circuitry 785. The second terminal of the flip-flop 790 is coupled to the logic circuitry 792. The third terminal of the flip-flop 790 is coupled to the programmable delay circuitry 705, the flip-flop 794, and may be coupled to the injection multiplication circuitry 145, 205. In the example of FIG. 7, the flip-flop 790 is structured as a data flip-flop (D flip-flop). Alternatively, with slight modifications, the flip-flop 790 may be modified or replaced with an alternative type of flip-flop.

The logic circuitry 792 has a first terminal, a second terminal, and a third terminal. The first terminal of the logic circuitry 792 is coupled to the flip-flop 790. The second and third terminals of the logic circuitry 792 are coupled to the programmable delay circuitry 705. Alternatively, the logic circuitry 792 may be replaced with combination logic or driver circuitry.

The flip-flop 794 has a first terminal, a second terminal, and a third terminal. The first terminal of the flip-flop 794 is coupled to the serializer circuitry 785. The second terminal of the flip-flop 794 is coupled to the logic circuitry 796. The third terminal of the flip-flop 794 is coupled to the programmable delay circuitry 705, the flip-flop 790, and may be coupled to the injection multiplication circuitry 145, 205. In the example of FIG. 7, the flip-flop 794 is structured as a data flip-flop (D flip-flop). Alternatively, with slight modifications, the flip-flop 794 may be modified or replaced with an alternative type of flip-flop.

The logic circuitry 796 has a first terminal, a second terminal, and a third terminal. The first terminal of the logic circuitry 796 is coupled to the flip-flop 794. The second and third terminals of the logic circuitry 796 are coupled to the programmable delay circuitry 705. Alternatively, the logic circuitry 796 may be replaced with combination logic or driver circuitry.

FIG. 8 is a flowchart representative of example operations 800 that may be executed, instantiated, or performed to implement the duty cycle correction circuitry 150, 600, 700 of FIGS. 1, 6, and 7. In the example of FIG. 8, the operations 800 begin at Block 810, at which the programmable delay circuitry 610, 705 of FIGS. 6 and 7 and the multiplexer circuitry 615, 710 of FIGS. 6 and 7 receive a clock signal. (Block 810). In some examples, a clock signal from the injection multiplication circuitry 145, 205 of FIGS. 1 and 2 controls the transistors 725, 730, 740, 745 of FIG. 7 and the flip-flops 790, 794.

The multiplexer circuitry 615, 710 receives delay values as coefficients. (Block 820). In some examples, the serializer circuitry 785 of FIG. 7 determines values of the coefficients 630, 635, 715, 720 of FIGS. 6 and 7. In such examples, the values of the coefficients 630, 635, 715, 720 correspond to a delay of the programmable delay circuitry 610, 705. Also, each of the coefficients 630, 635, 715, 720 correspond to either a rising edge or a falling edge of the clock signal from the injection multiplication circuitry 145, 205. For example, when the frequency of the clock signal from the injection multiplication circuitry 145, 205 is six times the frequency of the clock signal from the oscillator circuitry 135 of FIG. 1, the duty cycle correction circuitry 150, 600 includes twelve coefficients, such as the coefficients 630, 635, 715, 720. In such an example, six of the coefficients correspond to rising edges and six of the coefficients correspond to falling edges.

The multiplexer circuitry 615, 710 serializes the delay values. (Block 830). In some examples, the serializer circuitry 785 sequences setting the delay values by serializing the coefficients 630, 635, 715, 720. In such examples, the serializer circuitry 785 generates a first serial data stream and a second serial data stream. The serializer circuitry 785 generates the first serial data stream by sequencing the coefficients 630, 635, 715, 720 corresponding to rising edges. The serializer circuitry 785 generates the second serial data stream by sequencing the coefficients 630, 635, 715, 720 corresponding to falling edges. The serializer circuitry 785 supplies the serialized coefficients to the flip-flops 790, 794 of FIG. 7.

The multiplexer circuitry 615, 710 latches the serialized delay values using the clock signal. (Block 840). In some examples, the flip-flops 790, 794 receive the serialized coefficients from the serializer circuitry 785 and the clock signal from the injection multiplication circuitry 145, 205. In such examples, the flip-flops 790, 794 latch the coefficients responsive to edges of the clock signal. For example, the flip-flop 790 latches a delay value for a falling edge of the clock signal responsive to receiving a rising edge of the clock signal. In such examples, the flip-flop 794 latches the delay value for a rising edge of the clock signal responsive to receiving a falling edge of the clock signal. The flip-flops 790, 794 supply the latched delay values to the logic circuitry 792, 796 of FIG. 7.

The programmable delay circuitry 610, 705 delays rising and falling edges of the clock signal using the delay values as the delay values are latched. (Block 850). In some examples, the logic circuitry 792, 796 receive latched delay values from the flip-flops 790, 794. In such examples, the logic circuitry 792, 796 generates voltages to control the transistors 735, 750, 765, 780 of FIG. 7 responsive to the latched delay values. In some examples, the logic circuitry 792 controls the transistors 735, 780 using voltages that correspond to delay values from the flip-flop 790. In such examples, the logic circuitry 796 controls the transistors 750, 765 using voltages that correspond to delay values from the flip-flop 794. For example, when the latched delay value is a first value (e.g., 0x0), the logic circuitry 792 generates a first voltage, which controls the delays of the transistors 735, 780. In such examples, when the latched delay value is a second value (e.g., 0xF), the logic circuitry 796 generates a second voltage, which controls the delays of the transistors 750, 765.

In example operation, adjusting the voltage at the control terminal of the transistors 735, 750, 765, 780 adjusts a voltage dependent parasitic capacitance of the transistors 735, 750, 765, 780. The voltage dependent parasitic capacitance of the transistors 735, 750, 765, 780 determines the settling time needed to turn the transistors 735, 750, 765, 780 on or off. In such example operations, the settling time of the transistors 735, 780 determine the duration of time to set the delayed clock signal to a logic low (e.g., generate a falling edge) and the settling time of the transistors 750, 765 determine the duration of time to set the delayed clock signal to a logic high (e.g., generate a rising edge). Advantageously, the logic circuitry 792 sets the delay of falling edges of the clock signal responsive to supplying a voltage to the transistors 735, 780 corresponding to a latched delay value. Advantageously, the logic circuitry 796 sets the delay of rising edges of the clock signal responsive to supplying a voltage to the transistors 750, 765 corresponding to a latched delay value. Control proceeds to return to Block 810.

Although example methods are described with reference to the flowchart illustrated in FIG. 8, many other methods of implementing the duty cycle correction circuitry 150, 600, 700 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

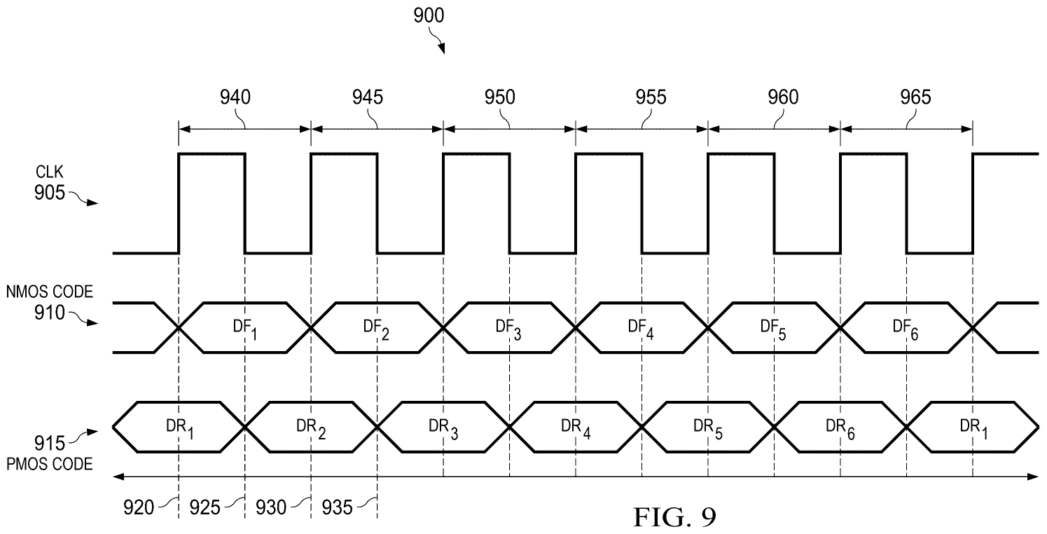

FIG. 9 is a timing diagram 900 of example operations of the duty cycle correction circuitry 150, 600, 700 of FIGS. 1, 6, and 7 to delay rising and falling edges of a clock signal from the injection multiplication circuitry 145, 205 of FIGS. 1 and 2. In the example of FIG. 9, the timing diagram 900 illustrates a clock signal 905 (CLK), a falling edge delay value signal 910 (NMOS Code), and a rising edge delay value signal 915. The clock signal 905 represents the clock signal output from the injection multiplication circuitry 145, 205 over time. The falling edge delay value signal 910 represents latching operations of the flip-flop 790 of FIG. 7 to supply a delay value that sets the delay of falling edges. The rising edge delay value signal 915 represents latching operations of the flip-flop 794 of FIG. 7 to supply a delay value that sets the delay of rising edges.

At a first time 920, the flip-flop 790 latches a first delay value, which corresponds to one of the coefficients 630, 635, 715, 720 of FIGS. 6 and 7, to set a delay of the transistors 735, 780 of FIG. 7 for a falling edge of the clock signal 905. At a second time 925, the logic circuitry 792 of FIG. 7 sets the voltage of the control terminals of the transistors 735, 780 responsive to the first delay value latched by the flip-flop 790 at the first time 920. Advantageously, adjusting the one of the coefficients 630, 635, 715, 720 corresponding to the first delay value adjusts the delay of the falling edge at the second time 925.

Also at the second time 925, the flip-flop 794 latches a second delay value, which corresponds to another one of the coefficients 630, 635, 715, 720, to set a delay of the transistors 750, 765 of FIG. 7 for a rising edge of the clock signal 905. At a third time 930, the logic circuitry 796 of FIG. 7 sets the voltage of the control terminals of the transistors 750, 765 responsive to the delay value latched by the flip-flop 794 at the second time 925. Also at the third time 930, the flip-flop 790 latches a third delay value, which corresponds to yet another one of the coefficients 630, 635, 715, 720, to set a delay of the transistors 735, 780 for a falling edge of the clock signal 905, which occurs at a fourth time 935. Advantageously, adjusting the coefficients 630, 635, 715, 720 adjusts delays of the clock signal 905.

The timing diagram 900 further illustrates a first example duty cycle 940, a second example duty cycle 945, a third example duty cycle 950, a fourth example duty cycle 955, a fifth example duty cycle 960, and a sixth example duty cycle 965. In some examples, where the injection multiplication circuitry 145, 205 generates the clock signal 905 to have a frequency that is six times the frequency of the oscillator circuitry 135 of FIG. 1, the duty cycles 940, 945, 950, 955, 960, 965 may vary responsive to the clock multiplier circuitry 140, 200 of FIGS. 1 and 2 and the injection multiplication circuitry 145, 205. Advantageously, adjusting the rising and falling edges of the clock signal 905 reduces variations between the duty cycles 940, 945, 950, 955, 960, 965. Advantageously, as further described below, the duty cycle estimation circuitry 155, 605 of FIGS. 1 and 6 determines the duty cycles 940, 945, 950, 955, 960, 965 and adjusts the coefficients 630, 635, 715, 720 to reduce variations and phase errors.

FIG. 10 is a schematic diagram of example duty cycle estimation circuitry 1000, which is an example of the duty cycle estimation circuitry 155, 605 of FIGS. 1 and 6. In the example of FIG. 10, the duty cycle estimation circuitry 1000 includes ring counter circuitry 1005, multiplexer circuitry 1010, filter circuitry 1015, comparator circuitry 1020, and coefficient controller circuitry 1025. The ring counter circuitry 1005 of FIG. 10 includes example ring clock control circuitry 1030, a first example flip-flop 1035, a second example flip-flop 1040, a third example flip-flop 1045, a fourth example flip-flop 1050, a fifth example flip-flop 1055, and a sixth example flip-flop 1060. The filter circuitry 1015 of FIG. 10 includes an example logic device 1065 and an example low pass filter 1070. The comparator circuitry 1020 of FIG. 10 includes example delay circuitry 1075 and an example comparator 1080. The coefficient controller circuitry 1025 of FIG. 10 includes example clock write circuitry 1085, example sequencing circuitry 1090, and example coefficient modifier circuitry 1095.

The ring counter circuitry 1005 is coupled to the multiplexer 1010, the coefficient controller circuitry 1025, and may be coupled to the duty cycle correction circuitry 150, 600, 700 of FIGS. 1, 6, and 7 and the AFE circuitry 110 of FIG. 1. The ring counter circuitry 1005 of FIG. 10 is an example of the ring counter circuitry 660 of FIG. 6. The multiplexer circuitry 1010 is coupled to the ring counter circuitry 1005, the filter circuitry 1015, and the coefficient controller circuitry 1025. The multiplexer circuitry 1010 of FIG. 10 is an example of the multiplexer circuitry 670 of FIG. 6. The filter circuitry 1015 is coupled to the multiplexer circuitry 1010 and the comparator circuitry 1020. The filter circuitry 1015 of FIG. 10 is an example of the filter circuitry 675 of FIG. 6. The comparator circuitry 1020 is coupled to the filter circuitry 1015 and the coefficient controller circuitry 1025. The comparator circuitry 1020 is an example of the comparator circuitry 680 of FIG. 6. The coefficient controller circuitry 1025 is coupled to the ring counter circuitry 1005, the multiplexer circuitry 1010, the comparator circuitry 1020, and may be coupled to the duty cycle correction circuitry 150, 600, 700. The coefficient controller circuitry 1025 is an example of the coefficient controller circuitry 685 of FIG. 6.

The ring clock control circuitry 1030 has a first terminal, a second terminal, a third terminal, a fourth terminal, a fifth terminal, and a sixth terminal. The first terminal of the ring clock control circuitry 1030 may be coupled to the duty cycle correction circuitry 150, 600, 700 and the AFE circuitry 110. The second, third, and fourth terminals of the ring clock control circuitry 1030 are coupled to the coefficient controller circuitry 1025. The fifth and sixth terminals of the ring clock control circuitry 1030 are coupled to the flip-flops 1035, 1040, 1045, 1050, 1055, 1060.

The flip-flop 1035 has an input terminal, an output terminal, a clock terminal, and a preset terminal. The input terminal of the flip-flop 1035 is coupled to the multiplexer circuitry 1010 and the flip-flop 1060. The output terminal of the flip-flop 1035 is coupled to the multiplexer circuitry 1010 and the flip-flop 1040. The flip-flop 1040 has an input terminal, an output terminal, a clock terminal, and a clear terminal. The input terminal of the flip-flop 1040 is coupled to the multiplexer circuitry 1010 and the flip-flop 1035. The output terminal of the flip-flop 1040 is coupled to the multiplexer circuitry 1010 and the flip-flop 1045. The flip-flop 1045 has an input terminal, an output terminal, a clock terminal, and a clear terminal. The input terminal of the flip-flop 1045 is coupled to the multiplexer circuitry 1010 and the flip-flop 1040. The output terminal of the flip-flop 1045 is coupled to the multiplexer circuitry 1010 and the flip-flop 1050. The flip-flop 1050 has an input terminal, an output terminal, a clock terminal, and a clear terminal. The input terminal of the flip-flop 1050 is coupled to the multiplexer circuitry 1010 and the flip-flop 1045. The output terminal of the flip-flop 1050 is coupled to the multiplexer circuitry 1010 and the flip-flop 1055. The flip-flop 1055 has an input terminal, an output terminal, a clock terminal, and a clear terminal. The input terminal of the flip-flop 1055 is coupled to the multiplexer circuitry 1010 and the flip-flop 1050. The output terminal of the flip-flop 1055 is coupled to the multiplexer circuitry 1010 and the flip-flop 1060. The flip-flop 1060 has an input terminal, an output terminal, a clock terminal, and a clear terminal. The input terminal of the flip-flop 1060 is coupled to the multiplexer circuitry 1010 and the flip-flop 1055. The output terminal of the flip-flop 1060 is coupled to the multiplexer circuitry 1010 and the flip-flop 1035.

The clock terminals of the flip-flops 1035, 1040, 1045, 1050, 1055, 1060 are coupled to the ring clock control circuitry 1030. The preset terminal of the flip-flop 1035 and the clear terminals of the flip-flops 1040, 1045, 1050, 1055, 1060 are coupled to the ring clock control circuitry 1030. In the example of FIG. 10, the flip-flops 1035, 1040, 1045, 1050, 1055, 1060 are structured as a ring counter, which is controlled by the ring clock control circuitry 1030. Also, the flip-flops 1035, 1040, 1045, 1050, 1055, 1060 are structured as a ring counter having six phases. Alternatively, the ring counter of the flip-flops 1035, 1040, 1045, 1050, 1055, 1060 may be modified to have any number of phases by adding or subtracting flip-flops. For example, when the injection multiplication circuitry 145 generates an output clock signal by multiplying an input clock signal by four, the ring counter circuitry 1005 may be modified to include eight flip-flops, which are structured as a ring counter with eight phases.

The logic device 1065 has a non-inverting input terminal, an inverting input terminal, and an output terminal. The non-inverting and inverting input terminals of the logic device 1065 are coupled to the multiplexer circuitry 1010. The output terminal of the logic device 1065 is coupled to the low pass filter 1070. In the example of FIG. 10, the logic device 1065 is an AND gate with an inverting input and a non-inverting input. Alternatively, the filter circuitry 1015 may be modified to have the logic device 1065 be replaced with an alternative type of logic gate or combinational logic.

The low pass filter 1070 has a first terminal and a second terminal. The first terminal of the low pass filter 1070 is coupled to the logic device 1065. The second terminal of the low pass filter 1070 is coupled to the comparator circuitry 1020. In some examples, the low pass filter 1070 is a resistor-capacitor (RC) circuit. Alternatively, the filter circuitry 1015 may be modified or replace the low pass filter 1070 with an alternative type of circuitry that utilizes timing characteristics to generate an output voltage, such as an LC circuit.

The delay circuitry 1075 has a first terminal and a second terminal. The first terminal of the delay circuitry 1075 is coupled to the filter circuitry 1015 and the comparator 1080. The second terminal of the delay circuitry 1075 is coupled to the comparator 1080. The delay circuitry 1075 is structured to delay a supply of a voltage from the filter circuitry 1015 by a delay duration. Alternatively, the comparator circuitry 1020 may be modified or replace the delay circuitry 1075 with alternative circuitry that stores an output of the filter circuitry 1015.

The comparator 1080 has a first terminal, a second terminal, and a third terminal. The first terminal of the comparator 1080 is coupled to the filter circuitry 1015 and the delay circuitry 1075. The second terminal of the comparator 1080 is coupled to the delay circuitry 1075. The third terminal of the comparator 1080 is coupled to the coefficient controller circuitry 1025.

The clock write circuitry 1085 has first terminal, a second terminal, a third terminal, and a fourth terminal. The first, second, and third terminals of the clock write circuitry 1085 are coupled to the ring counter circuitry 1005. The fourth terminal of the clock write circuitry 1085 is coupled to the sequencing circuitry 1090.

The sequencing circuitry 1090 has a first terminal, a second terminal, and a third terminal. The first terminal of the sequencing circuitry 1090 is coupled to the clock write circuitry 1085. The second terminal of the sequencing circuitry 1090 is coupled to the multiplexer circuitry 1010. The third terminal of the sequencing circuitry 1090 is coupled to the coefficient modifier circuitry 1095.

The coefficient modifier circuitry 1095 has a first terminal, a second terminal, and a third terminal. The first terminal of the coefficient modifier circuitry 1095 is coupled to the comparator circuitry 1020. The second terminal of the coefficient modifier circuitry 1095 is coupled to the sequencing circuitry 1090. The third terminal of the coefficient modifier circuitry 1095 may be coupled to the duty cycle correction circuitry 150, 600, 700.

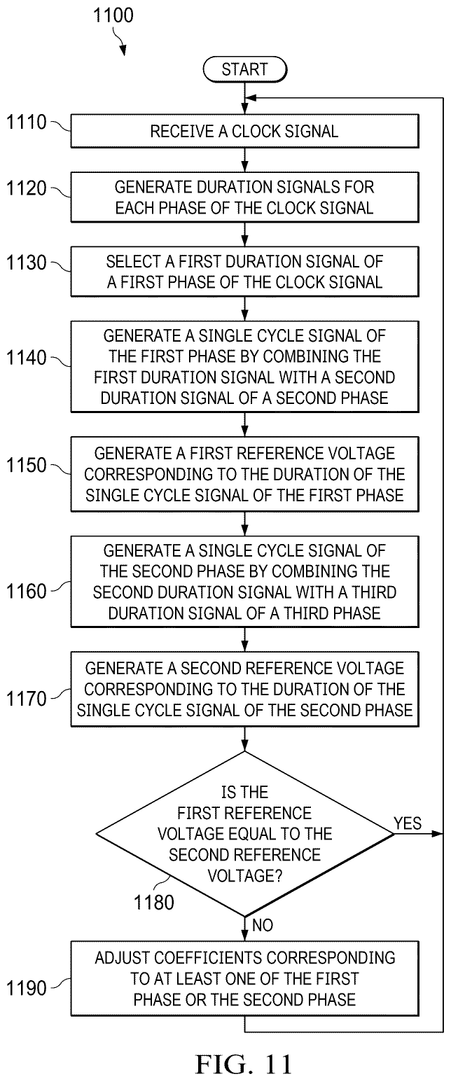

FIG. 11 is a flowchart representative of example operations 1100 that may be executed, instantiated, or performed to implement the duty cycle estimation circuitry 155, 605, 1000 of FIGS. 1, 6, and 10. In the example of FIG. 11, the operations 1100 begin at Block 1110, at which, the ring counter circuitry 660, 1005 of FIGS. 6 and 10 receive a clock signal. (Block 1110). In some examples, the ring counter circuitry 660, 1005 receives the delayed clock signal from the duty cycle correction circuitry 150, 600, 700 of FIGS. 1, 6, and 7.

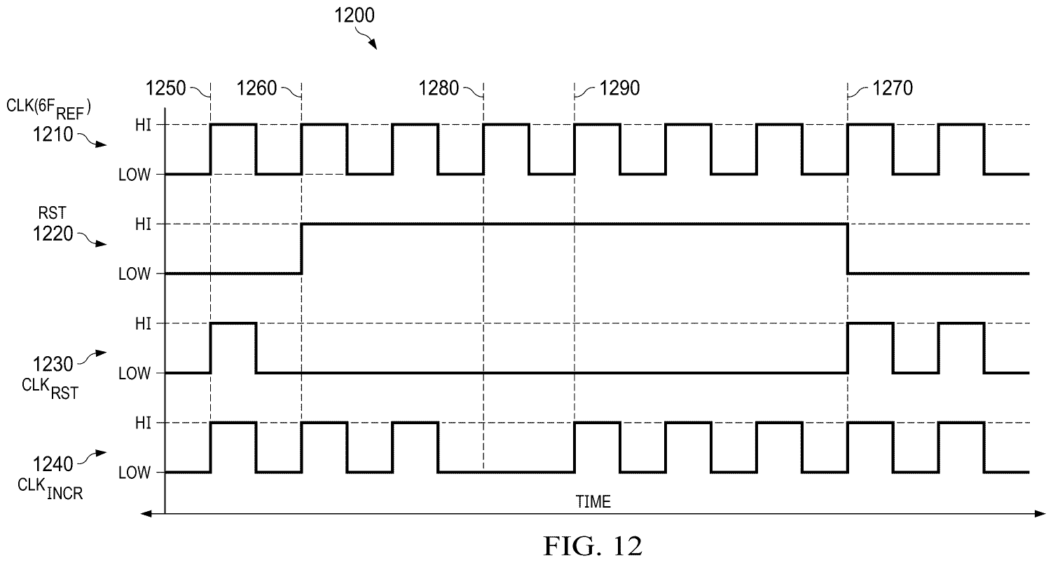

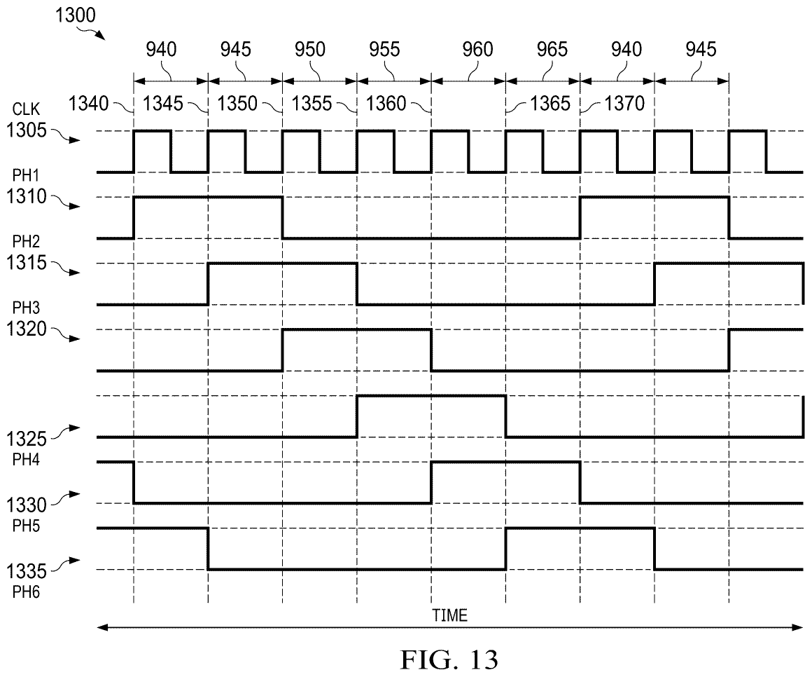

The ring counter circuitry 660, 1005 generates duration signals for each phase of the clock signal. (Block 1120). In some examples, the ring clock control circuitry 1030 receives the delayed clock signal from the duty cycle correction circuitry 150, 600, 700 and a flip clock signal (FLIP_CLK), a reset signal (RST_INP), and an increment signal (INCR) from the clock write circuitry 1085 of FIG. 10. In some example operations, the clock write circuitry 1085 uses serial peripheral interface (SPI) communication protocols to generate the flip clock signal, the reset signal, and the increment signal. In such example operations, the ring clock control circuitry 1030 generates a ring clock signal (CLK) and a reset signal (RST) responsive to receiving the clock signals, the reset signal, and the increment signal. Examples of the ring clock signal and the reset signal are illustrated and described in connection with FIG. 12, below. The flip-flops 1035, 1040, 1045, 1050, 1055, 1060 of FIG. 10 generate a plurality of duration signals responsive to the ring clock signal and the reset signal. Each of the duration signals represents two duty cycles of the delayed clock signal. For example, a first duration signal has a pulse equal to the duration of the duty cycles 940, 945 of FIG. 9. In such an example, a second duration signal has a pulse equal to the duration of the duty cycles 945, 950 of FIG. 9. Examples of the plurality of duration signals are illustrated and described in connection with FIG. 13, below.

The coefficient controller circuitry 685, 1025 of FIGS. 6 and 10 selects a first duration signal of a first phase of the clock signal. (Block 1130). In some examples, the sequencing circuitry 1090 of FIG. 10 configures the multiplexer circuitry 1010 of FIG. 10 and the clock write circuitry 1085 to supply a first duration signal. In such examples, the sequencing circuitry 1090 selects the duration signal responsive to sweeping through all duration signals (e.g., phases of the ring counter circuitry 1005).

The filter circuitry 675, 1015 of FIGS. 6 and 10 generates a single cycle signal of the first phase by combining the first duration signal with a second duration signal of a second phase. (Block 1140). In some examples, the logic device 1065 of FIG. 10 receives the selected duration signal and a following duration signal from the multiplexer circuitry 1010. In such examples, the logic device 1065 logically combines the duration signals to generate a single cycle signal that has a duty cycle approximately equal to a duty cycle shared between the duration signals.

For example, when a first duration signal represents the duty cycles 940, 945 and a second duration signal represents the duty cycles 945, 950, the logic device 1065 generates a single cycle signal having a duration equal to the duty cycle 945. In another example, when a first duration signal represents the duty cycles 950, 955 of FIG. 9 and a second duration signal represents the duty cycles 950, 955 of FIG. 9, the logic device 1065 generates a single cycle signal having a duration equal to the duty cycle 950. Advantageously, the single cycle signal has a duration equal to a single one of the duty cycles 940, 945, 950, 955, 960, 965 of FIG. 9.

The filter circuitry 675, 1015 generates a first reference voltage corresponding to the duration of the single cycle signal of the first phase. (Block 1150). In some examples, the low pass filter 1070 of FIG. 10 receives the single cycle signal from the logic device 1065. In such examples, the low pass filter 1070 charges an RC circuit to generate a reference voltage responsive to the duration of the single cycle signal. Advantageously, the low pass filter 1070 generates the reference voltage proportional to the duration of the single cycle signal. Advantageously, the reference voltage corresponds to the duration of the single cycle signal.

The filter circuitry 675, 1015 generates a single cycle signal of the second phase by combining the second duration signal with a third duration signal of a third phase. (Block 1160). In some examples, the logic device 1065 receives a duration signal that is subsequent to the selected duration signal of Block 1140 and a following duration signal from the multiplexer circuitry 1010. In such examples, the logic device 1065 logically combines the duration signals to generate another single cycle signal that has a duty cycle equal to a duty cycle shared between the duration signals. Advantageously, the single cycle signal has a duration equal to a single cycle of one of the duty cycles 940, 945, 950, 955, 960, 965 of FIG. 9.

The filter circuitry 675, 1015 generates a second reference voltage corresponding to the duration of the single cycle signal of the second phase. (Block 1170). In some examples, the low pass filter 1070 receives the single cycle signal from the logic device 1065. In such examples, the low pass filter 1070 charges an RC circuit to generate a reference voltage responsive to the duration of the single cycle signal. Advantageously, the low pass filter 1070 generates the reference voltage proportional to the duration of the single cycle signal. Advantageously, the reference voltage corresponds to the duration of the single cycle signal.

The comparator circuitry 680, 1020 determines if the first reference voltage is equal to the second reference voltage. (Block 1180). In some examples, the delay circuitry 1075 of FIG. 10 stores the first reference voltage when the filter circuitry 675, 1015 generates the second reference voltage. In such examples, the comparator 1080 of FIG. 10 compares the first reference voltage from the delay circuitry 1075 to the second reference voltage from the low pass filter 1070. If the first and second reference voltages are different, the comparator 1080 generates an output proportional to the difference. If the comparator circuitry 680, 1020 determines that the first reference voltage and the second reference voltage are equal, or at least within a threshold value of each other, (e.g., Block 1180 returns a result of YES), control proceeds to return to Block 1110 and proceed to Block 1130 where the coefficient controller circuitry 685, 1025 selects a different phase as the first phase.

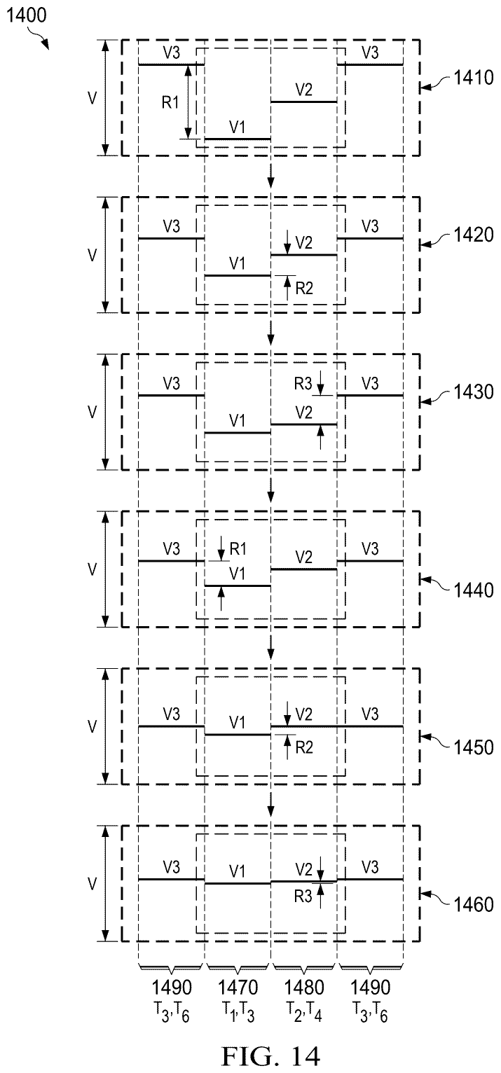

If the comparator circuitry 680, 1020 determines that the first reference voltage and the second reference voltage are not equal, or at least not within a threshold value of each other, (e.g., Block 1180 returns a result of NO), the coefficient controller circuitry 685, 1025 adjusts coefficients corresponding to at least one of the first phase of the second phase. (Block 1190). In some examples, the coefficient modifier circuitry 1095 of FIG. 10 receives the output of the comparator 1080 and an indication of the duty cycles being tested from the sequencing circuitry 1090. In such examples, the coefficient modifier circuitry 1095 adjusts at least one of the coefficients 630, 635, 715, 720 of FIGS. 6 and 7 that correspond to the duty cycles that are being tested responsive to the output of the comparator 1080. Example operations of the coefficient modifier circuitry 1095 to reduce variations in the reference voltages of duty cycles are illustrated and described in connection with FIG. 14. Control proceeds to return to Block 1110 and proceed to Block 1130 where the coefficient controller circuitry 685, 1025 selects a different phase as the first phase. Advantageously, the duty cycle estimation circuitry 155, 605, 1000 reduces variations in the duty cycles 940, 945, 950, 955, 960, 965 responsive to comparing the duration signals for each of the duty cycles 940, 945, 950, 955, 960, 965.

Although example methods are described with reference to the flowchart illustrated in FIG. 11, many other methods of implementing the duty cycle estimation circuitry 155, 605, 1000 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 12 is a timing diagram 1200 of example operations of the ring clock control circuitry 1030 of FIG. 10 and the clock write circuitry 1085 of FIG. 10. In the example of FIG. 12, the timing diagram 1200 includes a delayed clock signal 1210 (CLK(6F_{REF})), a reset signal 1220 (RST), a reset clock signal 1230 (CLK_{RST}), and an increment clock signal 1240 (CLK_{INCR}). The delayed clock signal 1210 illustrates the clock signal from the duty cycle correction circuitry 150, 600, 700 of FIGS. 1, 6, and 7.

The reset signal 1220 illustrates a reset output of the ring clock control circuitry 1030 of FIG. 10 responsive to the clock write circuitry 1085 of FIG. 10 resetting the ring counter circuitry 1005. The reset clock signal 1230 illustrates a clock output of the ring clock control circuitry 1030 responsive to the clock write circuitry 1085 resetting the ring counter circuitry 1005. In some examples, the clock write circuitry 1085 generates a reset signal (RST_INP) using SPI communications with the ring clock control circuitry 1030 to reset the flip-flops 1035, 1040, 1045, 1050, 1055, 1060 of FIG. 10. In such examples, the clock write circuitry 1085 periodically resets the ring counter circuitry 1005 to reduce the likelihood of errors modifying which of the flip-flops 1035, 1040, 1045, 1050, 1055, 1060 correspond to which duty cycle.

The increment clock signal 1240 represents the clock output of the ring clock control circuitry 1030 responsive to the clock write circuitry 1085 incrementing the ring counter circuitry 1005. In some examples, the clock write circuitry 1085 generates an increment signal (INCR) using SPI communications with the ring clock control circuitry 1030 to increment which of the flip-flops 1035, 1040, 1045, 1050, 1055, 1060 correspond to which duty cycle. In such examples, the clock write circuitry 1085 periodically increments the ring counter circuitry 1005 to reduce errors resulting from mismatches between the flip-flops 1035, 1040, 1045, 1050, 1055, 1060.

At a first time 1250, the delayed clock signal 1210, the reset clock signal 1230, and the increment clock signal 1240 are approximately equal to each other. At the first time 1250, the reset signal 1220 indicates that a reset operation is not occurring. At a second time 1260, the reset signal 1220 indicates that a reset operation of the ring counter circuitry 1005 is to occur. Between the times 1260, 1270, the reset clock signal 1230 remains set to a logical low. The reset signal 1220 remains set for a number of cycles of the delayed clock signal 1210 proportional to the number of the flip-flops 1035, 1040, 1045, 1050, 1055, 1060 to reset the states of the flip-flops 1035, 1040, 1045, 1050, 1055, 1060.

Between the times 1280, 1290, the increment clock signal 1240 skips a cycle of the delayed clock signal 1210. At the time 1280, the clock write circuitry 1085 uses the increment signal to increment which of the flip-flops 1035, 1040, 1045, 1050, 1055, 1060 correspond to which duty cycles. After skipping a cycle of the delayed clock signal 1210, the flip-flops 1035, 1040, 1045, 1050, 1055, 1060 represent different duty cycles of the delayed clock signal. Advantageously, the clock write circuitry 1085 reduces errors resulting from mismatch between the flip-flops 1035, 1040, 1045, 1050, 1055, 1060 by cycling each duty cycle through each of the flip-flops 1035, 1040, 1045, 1050, 1055, 1060.

FIG. 13 is a timing diagram 1300 of example operations of the flip-flops 1035, 1040, 1045, 1050, 1055, 1060 of FIG. 10 or more generally the ring counter circuitry 660, 1005 of FIGS. 6 and 10. In the example of FIG. 13, the timing diagram 1300 includes a delayed clock signal 1305, a first duration signal 1310 (ph1), a second duration signal 1315 (ph2), a third duration signal 1320 (ph3), a fourth duration signal 1325 (ph4), a fifth duration signal 1330 (ph5), and a sixth duration signal 1335 (ph6). In the example of FIG. 13, the example operations occur responsive to the frequency of the delayed clock signal 1305 being six times the frequency of the clock signal from the oscillator circuitry 135 of FIG. 1. Alternatively, the clock circuitry 120 of FIG. 1 may be modified to increase the frequency of the clock signal from the oscillator circuitry 135 by any multiple.

The delayed clock signal 1305 illustrates the clock signal from the duty cycle correction circuitry 150, 600, 700 of FIGS. 1, 6, and 7. The duration signal 1310 represents the duty cycles 940, 945 of FIG. 9. The duration signal 1315 represents the duty cycles 945, 950 of FIG. 9. The duration signal 1320 represents the duty cycles 950, 955 of FIG. 9. The duration signal 1325 represents the duty cycles 955, 960 of FIG. 9. The duration signal 1330 represents the duty cycles 960, 965 of FIG. 9. The duration signal 1330 represents the duty cycles 940, 965. Advantageously, variations in the duty cycles 940, 945, 950, 955, 960, 965 repeat every six cycles.

The duty cycle 940 corresponds to a difference between times 1340, 1345. The duty cycle 945 corresponds to a difference between times 1345, 1350. The duty cycle 950 corresponds to a difference between times 1350, 1355. The duty cycle 955 corresponds to a difference between times 1355, 1360. The duty cycle 960 corresponds to a difference between times 1360, 1365. The duty cycle 965 corresponds to a difference between times 1365, 1370.

However, the ring counter circuitry 660, 1005 is capable of generating two duty cycle wide pulses. Advantageously, the logic device 1065 of FIG. 10 logically combines two of the duration signals 1310, 1315, 1320, 1325, 1330, 1335 to generate single cycle signals having a pulse of a duration equal to the duration of the duty cycles 940, 945, 950, 955, 960, 965. For example, the logic device 1065 combines the duration signals 1310, 1315 to generate a single cycle signal having a duration equal to the duration between the times 1340, 1345, which is equal to the duty cycle 940. In another example, the logic device 1065 combines the duration signals 1315, 1320 to generate a single cycle signal having a duration equal to the duration between the times 1345, 1350, which is equal to the duty cycle 945. In yet another example, the logic device 1065 combines the duration signals 1310, 1335 to generate a single cycle signal having a duration equal to the duration between the times 1365, 1370, which is equal to the duty cycle 965.

FIG. 14 is a plot 1400 of example operations of the comparator circuitry 680, 1020 of FIGS. 6 and 10 and the coefficient controller circuitry 685, 1025 of FIGS. 6 and 10 to reduce variations between the duty cycles 940, 945, 950, 955, 960, 965 of FIGS. 9 and 13. In the example of FIG. 14, the plot 1400 includes first operations 1410, second operations 1420, third operations 1430, fourth operations 1440, fifth operations 1450, and sixth operations 1460. During the operations 1410, 1420, 1430, 1440, 1450, 1460, the plot 1400 illustrates a first example reference voltage 1470 (V1), a second example reference voltage 1480 (V2), and a third example reference voltage 1490 (V3).

The reference voltage 1470 represents a voltage resulting from the operations of Block 1150 of FIG. 11 responsive to the multiplexer circuitry 670, 1010 of FIGS. 6 and 10 supplying the duration signals 1310, 1315 of FIG. 13 to the filter circuitry 675, 1015 of FIGS. 6 and 10. Also, the reference voltage 1470 represents a voltage resulting from the operations of Block 1150 responsive to the multiplexer circuitry 670, 1010 supplying the duration signals 1325, 1330 of FIG. 13 to the filter circuitry 675, 1015. Advantageously, when the injection multiplication circuitry 145, 205 of FIGS. 1 and 2 multiplies the frequency of the clock signal from the clock multiplier circuitry 140, 200 of FIGS. 1 and 2, the duty cycles 940, 955 are equal.

The reference voltage 1480 represents a voltage resulting from the operations of Block 1150 responsive to the multiplexer circuitry 670, 1010 supplying the duration signals 1315, 1320 of FIG. 13 to the filter circuitry 675, 1015. Also, the reference voltage 1480 represents a voltage resulting from the operations of Block 1150 responsive to the multiplexer circuitry 670, 1010 supplying the duration signals 1330, 1335 of FIG. 13 to the filter circuitry 675, 1015.

The reference voltage 1490 represents a voltage resulting from the operations of Block 1150 responsive to the multiplexer circuitry 670, 1010 supplying the duration signals 1320, 1325 of FIG. 13 to the filter circuitry 675, 1015. Also, the reference voltage 1480 represents a voltage resulting from the operations of Block 1150 responsive to the multiplexer circuitry 670, 1010 supplying the duration signals 1335, 1310 of FIG. 13 to the filter circuitry 675, 1015.

During the operations 1410, the comparator circuitry 680, 1020 of FIGS. 6 and 10 compares the reference voltages 1470, 1490. In the example of FIG. 14, the coefficient controller circuitry 685, 1025 of FIGS. 6 and 10 determines a variation between the duty cycles 940, 950 or the duty cycles 955, 965 responsive to the comparison by the comparator circuitry 680, 1020. The coefficient controller circuitry 685, 1025 modifies the ones of the coefficients 630, 635, 715, 720 of FIGS. 6 and 7, which correspond to at least one of the rising or falling edges of the duty cycles 940, 950, 955, 965, to reduce the difference between the reference voltages 1470, 1490.

During the operations 1420, the comparator circuitry 680, 1020 compares the reference voltages 1470, 1480. In the example of FIG. 14, the coefficient controller circuitry 685, 1025 determines a variation between the duty cycles 940, 945 or the duty cycles 955, 960 responsive to the comparison by the comparator circuitry 680, 1020. The coefficient controller circuitry 685, 1025 modifies the ones of the coefficients 630, 635, 715, 720, which correspond to at least one of the rising or falling edges of the duty cycles 940, 945, 955, 960, to reduce the difference between the reference voltages 1470, 1480. Also, during the operations 1420, the reference voltages 1470, 1490 change from the operations 1410 responsive to the coefficient controller circuitry 685, 1025 modifying the ones of the coefficients 630, 635, 715, 720 that correspond to at least one of the rising or falling edges of the duty cycles 940, 950, 955, 965.

During the operations 1430, the comparator circuitry 680, 1020 compares the reference voltages 1480, 1490. In the example of FIG. 14, the coefficient controller circuitry 685, 1025 determines a variation between the duty cycles 945, 950 or the duty cycles 960, 965 responsive to the comparison by the comparator circuitry 680, 1020. The coefficient controller circuitry 685, 1025 modifies the ones of the coefficients 630, 635, 715, 720, which correspond to at least one of the rising or falling edges of the duty cycles 945, 950, 960, 965, to reduce the difference between the reference voltages 1480, 1490. Also, during the operations 1430, the reference voltages 1470, 1480 change from the operations 1420 responsive to the coefficient controller circuitry 685, 1025 modifying the ones of the coefficients 630, 635, 715, 720 that correspond to at least one of the rising or falling edges of the duty cycles 940, 945, 955, 960.

During the operations 1440, the comparator circuitry 680, 1020 compares the reference voltages 1470, 1490. In the example of FIG. 14, the coefficient controller circuitry 685, 1025 determines a variation between the duty cycles 940, 950 or the duty cycles 955, 965 responsive to the comparison by the comparator circuitry 680, 1020. The coefficient controller circuitry 685, 1025 modifies the ones of the coefficients 630, 635, 715, 720, which correspond to at least one of the rising or falling edges of the duty cycles 940, 950, 955, 965, to reduce the difference between the reference voltages 1470, 1490. Also, during the operations 1440, the reference voltages 1480, 1490 change from the operations 1430 responsive to the coefficient controller circuitry 685, 1025 modifying the ones of the coefficients 630, 635, 715, 720 that correspond to at least one of the rising or falling edges of the duty cycles 945, 950, 960, 965.

During the operations 1450, the comparator circuitry 680, 1020 compares the reference voltages 1470, 1480. In the example of FIG. 14, the coefficient controller circuitry 685, 1025 determines a variation between the duty cycles 940, 945 or the duty cycles 955, 960 responsive to the comparison by the comparator circuitry 680, 1020. The coefficient controller circuitry 685, 1025 modifies the ones of the coefficients 630, 635, 715, 720, which correspond to at least one of the rising or falling edges of the duty cycles 940, 945, 955, 960, to reduce the difference between the reference voltages 1470, 1480. Also, during the operations 1450, the reference voltages 1470, 1490 change from the operations 1440 responsive to the coefficient controller circuitry 685, 1025 modifying the ones of the coefficients 630, 635, 715, 720 that correspond to at least one of the rising or falling edges of the duty cycles 940, 950, 955, 965.

During the operations 1460, the comparator circuitry 680, 1020 compares the reference voltages 1480, 1490. In the example of FIG. 14, the coefficient controller circuitry 685, 1025 determines a variation between the duty cycles 945, 950 or the duty cycles 960, 965 responsive to the comparison by the comparator circuitry 680, 1020. The coefficient controller circuitry 685, 1025 modifies the ones of the coefficients 630, 635, 715, 720, which correspond to at least one of the rising or falling edges of the duty cycles 945, 950, 960, 965, to reduce the difference between the reference voltages 1480, 1490. Also, during the operations 1460, the reference voltages 1470, 1480 change from the operations 1450 responsive to the coefficient controller circuitry 685, 1025 modifying the ones of the coefficients 630, 635, 715, 720 that correspond to at least one of the rising or falling edges of the duty cycles 940, 945, 955, 960.

Advantageously, after the operations 1460, the coefficient controller circuitry 685, 1025 determines that the duty cycles 940, 945, 950, 955, 960, 965 are approximately, preferably equal, to each other responsive to comparisons by the comparator circuitry 680, 1020. In such example operations, the coefficient controller circuitry 685, 1025 holds the coefficients 630, 635, 715, 720. Advantageously, the duty cycle correction circuitry 150, 600, 700 of FIGS. 1, 6, and 7 and the duty cycle estimation circuitry 155, 605, 1000 of FIGS. 1, 6, and 10 reduce variations between the duty cycles 940, 945, 950, 955, 960, 965. Alternatively, the duty cycle correction circuitry 150, 600, 700 and the duty cycle estimation circuitry 155, 605, 1000 may be modified to correct any number of duty cycles.

While an example manner of implementing the coefficient controller circuitry 685, 1025 is illustrated in FIGS. 6 and 10, one or more of the elements, processes, or devices illustrated in FIGS. 6 and 10 may be combined, divided, re-arranged, omitted, eliminated, or implemented in any other way. Further, the clock write circuitry 1085 of FIG. 10, the sequencing circuitry 1090 of FIG. 10, the coefficient modifier circuitry 1095 of FIG. 10, or, more generally, the example coefficient controller circuitry 685, 1025 of FIGS. 6 and 10, may be implemented by hardware alone or by hardware in combination with software or firmware. Thus, for example, any of the clock write circuitry 1085 of FIG. 10, the sequencing circuitry 1090 of FIG. 10, the coefficient modifier circuitry 1095 of FIG. 10, or, more generally, the example coefficient controller circuitry 685, 1025, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example coefficient controller circuitry 685, 1025 of FIGS. 6 and 10 may include one or more elements, processes, or devices in addition to, or instead of, those illustrated in FIGS. 6 and 10, or may include more than one of any or all of the illustrated elements, processes and devices.

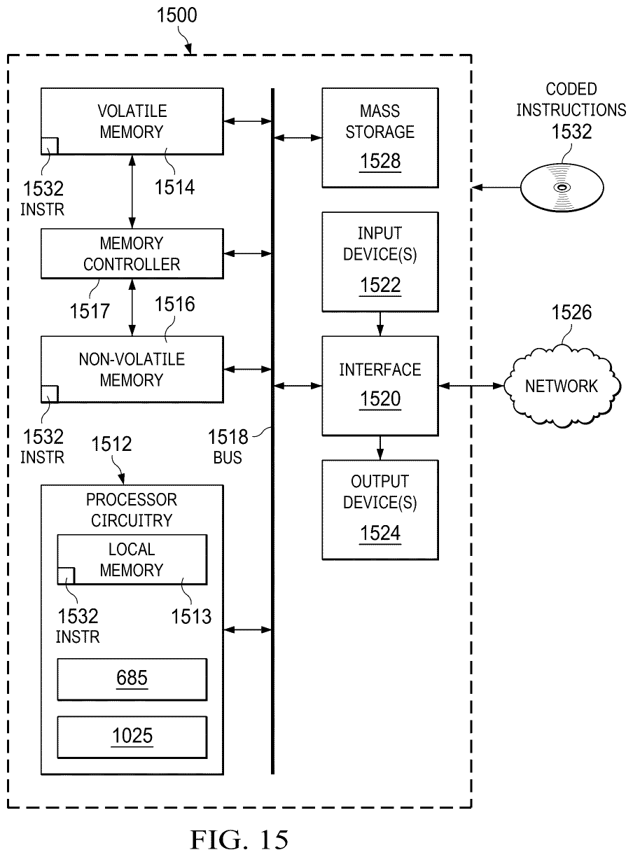

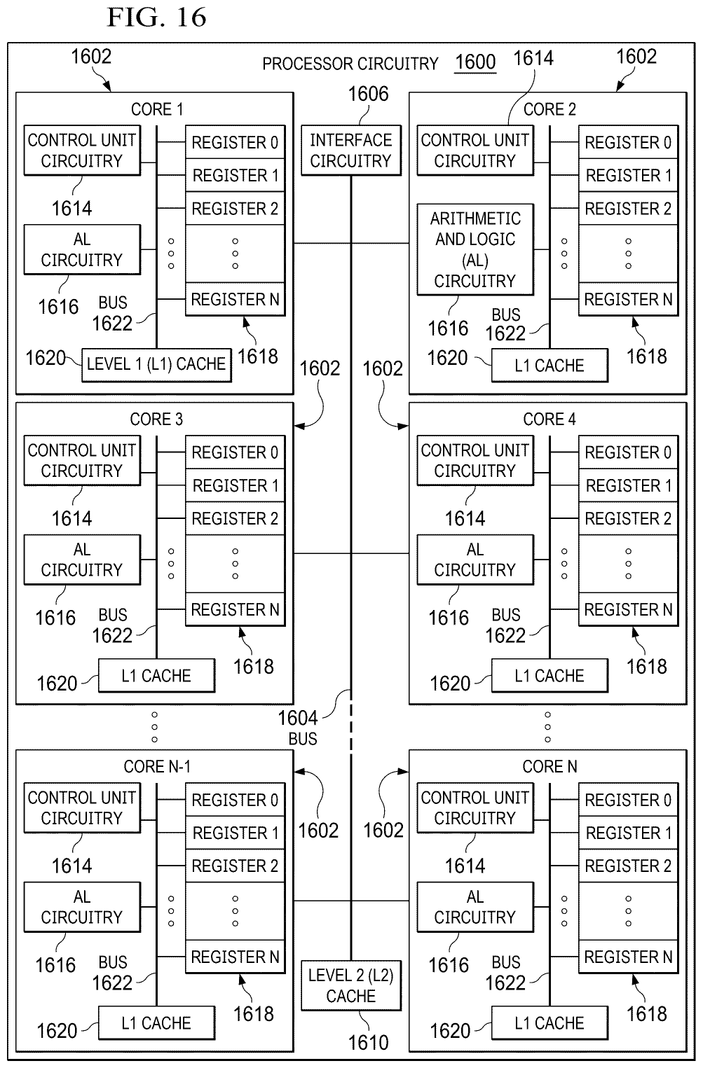

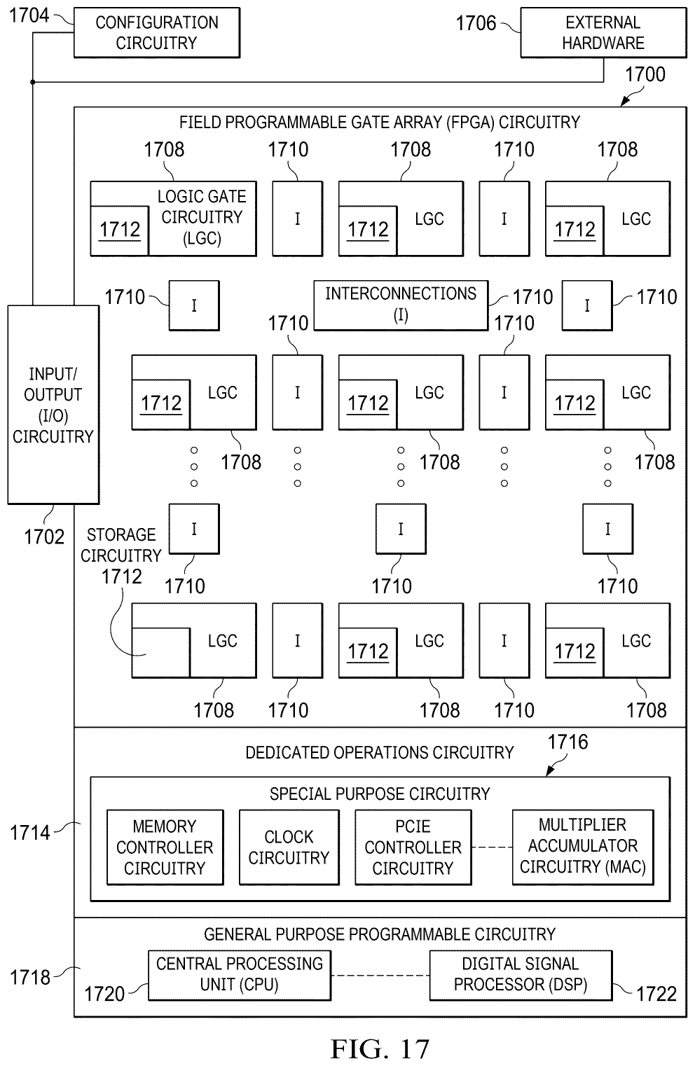

Flowchart(s) representative of example machine-readable instructions, which may be executed by programmable circuitry to implement or instantiate the coefficient controller circuitry 685, 1025 of FIGS. 6 and 10 or representative of example operations which may be performed by programmable circuitry to implement or instantiate the coefficient controller circuitry 685, 1025 of FIGS. 6 and 10, are shown in FIG. 11. The machine-readable instructions may be one or more executable programs or portion(s) of one or more executable programs for execution by programmable circuitry such as the programmable circuitry 1512 shown in the example programmable circuitry platform 1500 described below in connection with FIG. 15 or may be one or more function(s) or portion(s) of functions to be performed by the example programmable circuitry (e.g., an FPGA) described below in connection with FIG. 16 or 17. In some examples, the machine-readable instructions cause an operation, a task, etc., to be carried out or performed in an automated manner in the real world. As used herein, “automated” means without human involvement.

The program may be embodied in instructions (e.g., software or firmware) stored on one or more non-transitory computer readable or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 11, many other methods of implementing the example coefficient controller circuitry 685, 1025 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete or integrated analog or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, and the parts when decrypted, decompressed, or combined form a set of computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include instructions or program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 11 may be implemented using executable instructions (e.g., computer readable or machine-readable instructions) stored on one or more non-transitory computer readable or machine-readable media. As used herein, the terms non-transitory computer readable medium, non-transitory computer readable storage medium, non-transitory machine-readable medium, or non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, or for caching of the information). As used herein, the terms “non-transitory computer readable storage device” and “non-transitory machine-readable storage device” are defined to include any physical (mechanical, magnetic, or electrical) hardware to retain information for a time period, but to exclude propagating signals and to exclude transmission media. Examples of non-transitory computer readable storage devices and non-transitory machine-readable storage devices include random access memory of any type, read only memory of any type, solid state memory, flash memory, optical discs, magnetic disks, disk drives, or redundant array of independent disks (RAID) systems. As used herein, the term “device” refers to physical structure such as mechanical or electrical equipment, hardware, or circuitry that may or may not be configured by computer readable instructions, machine-readable instructions, etc., or manufactured to execute computer-readable instructions, machine-readable instructions, etc.

FIG. 15 is a block diagram of an example programmable circuitry platform 1500 structured to execute or instantiate the example machine-readable instructions or the example operations of FIG. 11 to implement the coefficient controller circuitry 685, 1025 of FIGS. 6 and 10. The programmable circuitry platform 1500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a gaming console, a headset (e.g., an augmented reality (AR) headset, a virtual reality (VR) headset, etc.) or other wearable device, or any other type of computing or electronic device.

The programmable circuitry platform 1500 of the illustrated example includes programmable circuitry 1512. The programmable circuitry 1512 of the illustrated example is hardware. For example, the programmable circuitry 1512 can be implemented by one or more integrated circuits, logic circuits, FPGAs, microprocessors, CPUs, GPUs, DSPs, or microcontrollers from any desired family or manufacturer. The programmable circuitry 1512 may be implemented by one or more semiconductor based (e.g., silicon based) devices. In this example, the programmable circuitry 1512 implements the coefficient controller circuitry 685, 1025 of FIGS. 6 and 10.

The programmable circuitry 1512 of the illustrated example includes a local memory 1513 (e.g., a cache, registers, etc.). The programmable circuitry 1512 of the illustrated example is in communication with main memory 1514, 1516, which includes a volatile memory 1514 and a non-volatile memory 1516, by a bus 1518. The volatile memory 1514 may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory 1516 may be implemented by flash memory or any other desired type of memory device. Access to the main memory 1514, 1516 of the illustrated example is controlled by a memory controller 1517. In some examples, the memory controller 1517 may be implemented by one or more integrated circuits, logic circuits, microcontrollers from any desired family or manufacturer, or any other type of circuitry to manage the flow of data going to and from the main memory 1514, 1516.

The programmable circuitry platform 1500 of the illustrated example also includes interface circuitry 1520. The interface circuitry 1520 may be implemented by hardware in any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1522 are connected to the interface circuitry 1520. The input device(s) 1522 permit(s) a user (e.g., a human user, a machine user, etc.) to enter data or commands into the programmable circuitry 1512. The input device(s) 1522 can be implemented by, for example, an audio sensor, a microphone, a camera (still or video), a keyboard, a button, an isopoint device, or a voice recognition system.

One or more output devices 1524 are also connected to the interface circuitry 1520 of the illustrated example. The output device(s) 1524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1520 of the illustrated example, thus, may include a graphics driver card, a graphics driver chip, or graphics processor circuitry such as a GPU.

The interface circuitry 1520 of the illustrated example also includes a communication device such as a transmitter, a receiver, a transceiver, a modem, a residential gateway, a wireless access point, or a network interface to facilitate exchange of data with external machines (e.g., computing devices of any kind) by a network 1526. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1500 of the illustrated example also includes one or more mass storage discs or devices 1528 to store firmware, software, or data. Examples of such mass storage discs or devices 1528 include magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices or SSDs.

The machine-readable instructions 1532, which may be implemented by the machine-readable instructions of FIG. 11, may be stored in the mass storage device 1528, in the volatile memory 1514, in the non-volatile memory 1516, or on at least one non-transitory computer readable storage medium such as a CD or DVD which may be removable.

FIG. 16 is a block diagram of an example implementation of the programmable circuitry 1512 of FIG. 15. In this example, the programmable circuitry 1512 of FIG. 15 is implemented by a microprocessor 1600. For example, the microprocessor 1600 may be a general-purpose microprocessor (e.g., general-purpose microprocessor circuitry). The microprocessor 1600 executes some or all of the machine-readable instructions of the flowcharts of FIG. 11 to effectively instantiate the circuitry of FIGS. 1, 6, and 10 as logic circuits to perform operations corresponding to those machine-readable instructions. In some such examples, the circuitry of FIGS. 6 and 10 is instantiated by the hardware circuits of the microprocessor 1600 in combination with the machine-readable instructions. For example, the microprocessor 1600 may be implemented by multi-core hardware circuitry such as a CPU, a DSP, a GPU, an XPU, etc. Although it may include any number of example cores 1602 (e.g., 1 core), the microprocessor 1600 of this example is a multi-core semiconductor device including N cores. The cores 1602 of the microprocessor 1600 may operate independently or may cooperate to execute machine-readable instructions. For example, machine code corresponding to a firmware program, an embedded software program, or a software program may be executed by one of the cores 1602 or may be executed by multiple ones of the cores 1602 at the same or different times. In some examples, the machine code corresponding to the firmware program, the embedded software program, or the software program is split into threads and executed in parallel by two or more of the cores 1602. The software program may correspond to a portion or all of the machine-readable instructions or operations represented by the flowcharts of FIG. 11.

The cores 1602 may communicate by a first example bus 1604. In some examples, the first bus 1604 may be implemented by a communication bus to effectuate communication associated with one(s) of the cores 1602. For example, the first bus 1604 may be implemented by at least one of an Inter-Integrated Circuit (I2C) bus, a Serial Peripheral Interface (SPI) bus, a PCI bus, or a PCIe bus. Also or alternatively, the first bus 1604 may be implemented by any other type of computing or electrical bus. The cores 1602 may obtain data, instructions, or signals from one or more external devices by example interface circuitry 1606. The cores 1602 may output data, instructions, or signals to the one or more external devices by the interface circuitry 1606. Although the cores 1602 of this example include example local memory 1620 (e.g., Level 1 (L1) cache that may be split into an L1 data cache and an L1 instruction cache), the microprocessor 1600 also includes example shared memory 1610 that may be shared by the cores (e.g., Level 2 (L2 cache)) for high-speed access to data or instructions. Data or instructions may be transferred (e.g., shared) by writing to or reading from the shared memory 1610. The local memory 1620 of each of the cores 1602 and the shared memory 1610 may be part of a hierarchy of storage devices including multiple levels of cache memory and the main memory (e.g., the main memory 1514, 1516 of FIG. 15). Also, higher levels of memory in the hierarchy exhibit lower access time and have smaller storage capacity than lower levels of memory. Changes in the various levels of the cache hierarchy are managed (e.g., coordinated) by a cache coherency policy.

Each core 1602 may be referred to as a CPU, DSP, GPU, etc., or any other type of hardware circuitry. Each core 1602 includes control unit circuitry 1614, arithmetic and logic (AL) circuitry (sometimes referred to as an ALU) 1616, a plurality of registers 1618, the local memory 1620, and a second example bus 1622. Other structures may be present. For example, each core 1602 may include vector unit circuitry, single instruction multiple data (SIMD) unit circuitry, load/store unit (LSU) circuitry, branch/jump unit circuitry, floating-point unit (FPU) circuitry, etc. The control unit circuitry 1614 includes semiconductor-based circuits structured to control (e.g., coordinate) data movement within the corresponding core 1602. The AL circuitry 1616 includes semiconductor-based circuits structured to perform one or more mathematic or logic operations on the data within the corresponding core 1602. The AL circuitry 1616 of some examples performs integer-based operations. In other examples, the AL circuitry 1616 also performs floating-point operations. In yet other examples, the AL circuitry 1616 may include first AL circuitry that performs integer-based operations and second AL circuitry that performs floating-point operations. In some examples, the AL circuitry 1616 may be referred to as an Arithmetic Logic Unit (ALU).

The registers 1618 are semiconductor-based structures to store data or instructions such as results of one or more of the operations performed by the AL circuitry 1616 of the corresponding core 1602. For example, the registers 1618 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1618 may be arranged in a bank as shown in FIG. 16. Alternatively, the registers 1618 may be organized in any other arrangement, format, or structure, such as by being distributed throughout the core 1602 to shorten access time. The second bus 1622 may be implemented by at least one of an I2C bus, a SPI bus, a PCI bus, or a PCIe bus.

Each core 1602 or, more generally, the microprocessor 1600 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1600 is a semiconductor device fabricated to include many transistors interconnected to implement the structures described above in one or more integrated circuits (ICs) contained in one or more packages.

The microprocessor 1600 may include or cooperate with one or more accelerators (e.g., acceleration circuitry, hardware accelerators, etc.). In some examples, accelerators are implemented by logic circuitry to perform certain tasks more quickly or efficiently than can be done by a general-purpose processor. Examples of accelerators include ASICs and FPGAs such as those described herein. A GPU, DSP or other programmable device can also be an accelerator. Accelerators may be on-board the microprocessor 1600, in the same chip package as the microprocessor 1600 or in one or more separate packages from the microprocessor 1600.

FIG. 17 is a block diagram of another example implementation of the programmable circuitry 1512 of FIG. 15. In this example, the programmable circuitry 1512 is implemented by FPGA circuitry 1700. For example, the FPGA circuitry 1700 may be implemented by an FPGA. The FPGA circuitry 1700 can be used, for example, to perform operations that could otherwise be performed by the example microprocessor 1600 of FIG. 16 executing corresponding machine-readable instructions. However, once configured, the FPGA circuitry 1700 instantiates the operations or functions corresponding to the machine-readable instructions in hardware and, thus, can often execute the operations/functions faster than they could be performed by a general-purpose microprocessor executing the corresponding software.

More specifically, in contrast to the microprocessor 1600 of FIG. 16 described above (which is a general purpose device that may be programmed to execute some or all of the machine-readable instructions represented by the flowchart(s) of FIG. 11 but whose interconnections and logic circuitry are fixed once fabricated), the FPGA circuitry 1700 of the example of FIG. 17 includes interconnections and logic circuitry that may be configured, structured, programmed, or interconnected in different ways after fabrication to instantiate, for example, some or all of the operations/functions corresponding to the machine-readable instructions represented by the flowchart(s) of FIG. 11. In particular, the FPGA circuitry 1700 may be thought of as an array of logic gates, interconnections, and switches. The switches can be programmed to change how the logic gates are interconnected by the interconnections, effectively forming one or more dedicated logic circuits (unless and until the FPGA circuitry 1700 is reprogrammed). The configured logic circuits enable the logic gates to cooperate in different ways to perform different operations on data received by input circuitry. Those operations may correspond to some or all of the instructions (e.g., the software or firmware) represented by the flowchart(s) of FIG. 11. As such, the FPGA circuitry 1700 may be configured and structured to effectively instantiate some or all of the operations/functions corresponding to the machine-readable instructions of the flowchart(s) of FIG. 11 as dedicated logic circuits to perform the operations/functions corresponding to those software instructions in a dedicated manner analogous to an ASIC. Therefore, the FPGA circuitry 1700 may perform the operations/functions corresponding to the some or all of the machine-readable instructions of FIG. 11 faster than the general-purpose microprocessor can execute the same.

In the example of FIG. 17, the FPGA circuitry 1700 is configured and structured in response to being programmed (or reprogrammed one or more times) based on a binary file. In some examples, the binary file may be compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1700 of FIG. 17 may access or load the binary file to structure the FPGA circuitry 1700 of FIG. 17 to perform the one or more operations/functions. For example, the binary file may be implemented by a bit stream (e.g., one or more computer-readable bits, one or more machine-readable bits, etc.), data (e.g., computer-readable data, machine-readable data, etc.), or machine-readable instructions accessible to the FPGA circuitry 1700 of FIG. 17 to structure the FPGA circuitry 1700 of FIG. 17, or portion(s) thereof.

In some examples, the binary file is compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, or otherwise output from the uniform software platform based on the second instructions. In some examples, the FPGA circuitry 1700 of FIG. 17 may access or load the binary file to structure the FPGA circuitry 1700 of FIG. 17 to perform the one or more operations/functions. For example, the binary file may be implemented by a bit stream (e.g., one or more computer-readable bits, one or more machine-readable bits, etc.), data (e.g., computer-readable data, machine-readable data, etc.), or machine-readable instructions accessible to the FPGA circuitry 1700 of FIG. 17 to structure the FPGA circuitry 1700 of FIG. 17, or portion(s) thereof.

The FPGA circuitry 1700 of FIG. 17 includes example input/output (I/O) circuitry 1702 to obtain or output data to/from example configuration circuitry 1704 or external hardware 1706. For example, the configuration circuitry 1704 may be implemented by interface circuitry that may obtain a binary file, which may be implemented by a bit stream, data, or machine-readable instructions, to configure the FPGA circuitry 1700, or portion(s) thereof. In some such examples, the configuration circuitry 1704 may obtain the binary file from a user, a machine (e.g., hardware circuitry (e.g., programmable or dedicated circuitry) that may implement an Artificial Intelligence/Machine Learning (AI/ML) model to generate the binary file), etc., or any combination(s) thereof). In some examples, the external hardware 1706 may be implemented by external hardware circuitry. For example, the external hardware 1706 may be implemented by the microprocessor 1600 of FIG. 16.

The FPGA circuitry 1700 also includes an array of example logic gate circuitry 1708, a plurality of example configurable interconnections 1710, and example storage circuitry 1712. The logic gate circuitry 1708 and the configurable interconnections 1710 are configurable to instantiate one or more operations/functions that may correspond to at least some of the machine-readable instructions of FIG. 11 or other desired operations. The logic gate circuitry 1708 shown in FIG. 17 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1708 to enable configuration of the electrical structures or the logic gates to form circuits to perform desired operations/functions. The logic gate circuitry 1708 may include other electrical structures such as look-up tables (LUTs), registers (e.g., flip-flops or latches), multiplexers, etc.

The configurable interconnections 1710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1708 to program desired logic circuits.

The storage circuitry 1712 of the illustrated example is structured to store result(s) of the one or more of the operations performed by corresponding logic gates. The storage circuitry 1712 may be implemented by registers or the like. In the illustrated example, the storage circuitry 1712 is distributed amongst the logic gate circuitry 1708 to facilitate access and increase execution speed.

The example FPGA circuitry 1700 of FIG. 17 also includes example dedicated operations circuitry 1714. In this example, the dedicated operations circuitry 1714 includes special purpose circuitry 1716 that may be invoked to implement commonly used functions to avoid the need to program those functions in the field. Examples of such special purpose circuitry 1716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1700 may also include example general purpose programmable circuitry 1718 such as an example CPU 1720 or an example DSP 1722. Other general purpose programmable circuitry 1718 may also or alternatively be present such as a GPU, an XPU, etc., that can be programmed to perform other operations.

Although FIGS. 16 and 17 illustrate two example implementations of the programmable circuitry 1512 of FIG. 15, many other approaches are contemplated. For example, FPGA circuitry may include an on-board CPU, such as one or more of the example CPU 1720 of FIG. 16. Therefore, the programmable circuitry 1512 of FIG. 15 may also be implemented by combining at least the example microprocessor 1600 of FIG. 16 and the example FPGA circuitry 1700 of FIG. 17. In some such hybrid examples, one or more cores 1602 of FIG. 16 may execute a first portion of the machine-readable instructions represented by the flowchart(s) of FIG. 11 to perform first operation(s)/function(s), the FPGA circuitry 1700 of FIG. 17 may be configured or structured to perform second operation(s)/function(s) corresponding to a second portion of the machine-readable instructions represented by the flowcharts of FIG. 11, or an ASIC may be configured and structured to perform third operation(s)/function(s) corresponding to a third portion of the machine-readable instructions represented by the flowcharts of FIG. 11.

Some or all of the circuitry of FIGS. 6 and 10 may, thus, be instantiated at the same or different times. For example, same or different portion(s) of the microprocessor 1600 of FIG. 16 may be programmed to execute portion(s) of machine-readable instructions at the same or different times. In some examples, same or different portion(s) of the FPGA circuitry 1700 of FIG. 17 may be configured or structured to perform operations/functions corresponding to portion(s) of machine-readable instructions at the same or different times.

In some examples, some or all of the circuitry of FIGS. 6 and 10 may be instantiated, for example, in one or more threads executing concurrently or in series. For example, the microprocessor 1600 of FIG. 16 may execute machine-readable instructions in one or more threads executing concurrently or in series. In some examples, the FPGA circuitry 1700 of FIG. 17 may be configured and structured to carry out operations/functions concurrently or in series. Moreover, in some examples, some or all of the circuitry of FIGS. 6 and 10 may be implemented within one or more virtual machines or containers executing on the microprocessor 1600 of FIG. 16.

In some examples, the programmable circuitry 1512 of FIG. 15 may be in one or more packages. For example, the microprocessor 1600 of FIG. 16 or the FPGA circuitry 1700 of FIG. 17 may be in one or more packages. In some examples, an XPU may be implemented by the programmable circuitry 1512 of FIG. 15, which may be in one or more packages. For example, the XPU may include a CPU (e.g., the microprocessor 1600 of FIG. 16, the CPU 1720 of FIG. 17, etc.) in one package, a DSP (e.g., the DSP 1722 of FIG. 17) in another package, a GPU in yet another package, and an FPGA (e.g., the FPGA circuitry 1700 of FIG. 17) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” refers to implementations including any of (1) at least one A, (2) at least one B, or (3) at least one A and at least one B. Similarly, as used herein in the context of describing structures, components, items, objects and/or things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+100 milli seconds.

As used herein, the phrase “in communication,” including variations thereof, encompasses direct communication or indirect communication through one or more intermediary components, and does not require direct physical (e.g., wired) communication or constant communication, but rather also includes selective communication at periodic intervals, scheduled intervals, aperiodic intervals, or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure or function. These identifiers as used in the detailed description do not necessarily align with those used in the claims.

A device that is “configured to” perform a task or function may be configured (e.g., programmed or hardwired) at a time of manufacturing by a manufacturer to perform the function or may be configurable (or re-configurable) by a user after manufacturing to perform the function or other additional or alternative functions. The configuring may be through firmware or software programming of the device, through a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as resistors, capacitors, or inductors), or one or more sources (such as voltage or current sources) may instead include only the semiconductor elements within a single physical device (e.g., a semiconductor die or integrated circuit (IC) package) and may be adapted to be coupled to at least some of the passive elements or the sources to form the described structure either at a time of manufacture or after a time of manufacture, for example, by an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
first frequency multiplier circuitry having a terminal; and
second frequency multiplier circuitry including:
first current source circuitry having a terminal;
a first transistor having a first terminal, a second terminal, and a control terminal, the first terminal of the first transistor coupled to the terminal of the first current source circuitry, the control terminal of the first transistor coupled to the terminal of the first frequency multiplier circuitry;
second current source circuitry having a terminal;
a second transistor having a first terminal and a second terminal, the first terminal of the second transistor coupled to the terminal of the second current source circuitry;
an inductor having a first terminal and a second terminal;
a capacitor having a first terminal and a second terminal, the first terminal of the capacitor coupled to the first terminal of the inductor; and
an amplifier having a terminal coupled to the second terminal of the first transistor, the second terminal of the second transistor, the second terminal of the inductor, and the second terminal of the capacitor.

2. The apparatus of claim 1, wherein the terminal of the first frequency multiplier circuitry is a first terminal, the first frequency multiplier circuitry further having a second terminal, the apparatus further comprising oscillator circuitry having a terminal coupled to the second terminal of the first frequency multiplier circuitry.

3. The apparatus of claim 1, wherein the terminal of the amplifier is a first terminal, the amplifier further having a second terminal, the apparatus further comprising:
duty cycle correction circuitry having a first terminal, a second terminal, and a third terminal, the first terminal of the duty cycle correction circuitry coupled to the second terminal of the amplifier; and
duty cycle estimation circuitry having a first terminal and a second terminal, the first terminal of the duty cycle estimation circuitry coupled to the second terminal of the duty cycle correction circuitry, the second terminal of the duty cycle estimation circuitry coupled to the third terminal of the duty cycle correction circuitry.

4. The apparatus of claim 3, further comprising transmitter circuitry having a terminal coupled to the second terminal of the duty cycle correction circuitry and the first terminal of the duty cycle estimation circuitry.

5. The apparatus of claim 3, wherein the duty cycle estimation circuitry comprising:
ring counter circuitry having a first terminal, and a second terminal, the first terminal of the ring counter circuitry coupled to the second terminal of the duty cycle correction circuitry;
multiplexer circuitry having a first terminal and a second terminal, the first terminal of the multiplexer circuitry coupled to the second terminal of the ring counter circuitry;
filter circuitry having a first terminal and a second terminal, the first terminal of the filter circuitry coupled to the second terminal of the multiplexer circuitry;
comparator circuitry having a first terminal and a second terminal, the first terminal of the comparator circuitry coupled to the second terminal of the filter circuitry; and
coefficient controller circuitry having a first terminal and a second terminal, the first terminal of the coefficient controller circuitry coupled to the second terminal of the comparator circuitry, the second terminal of the coefficient controller circuitry coupled to the third terminal of the duty cycle correction circuitry.

6. The apparatus of claim 1, wherein the terminal of the amplifier is a first terminal, the amplifier further having a second terminal, the apparatus further comprising duty cycle correction circuitry having a terminal coupled to the second terminal of the amplifier, the duty cycle correction circuitry comprising:
programmable delay circuitry having a first terminal and a second terminal, the first terminal of the programmable delay circuitry coupled to the second terminal of the amplifier; and
multiplexer circuitry having a terminal coupled to the second terminal of the programmable delay circuitry.

7. The apparatus of claim 1, wherein the terminal of the first frequency multiplier circuitry is a first terminal, the first frequency multiplier circuitry further having a second terminal, the inductor is a first inductor, the capacitor is a first capacitor, the second transistor further has a control terminal, the terminal of the amplifier is a first terminal, the amplifier further has a second terminal, and the apparatus further comprising:
a third transistor having a first terminal, a second terminal, and a control terminal, the first terminal of the third transistor is coupled to the first terminal of the first transistor and the terminal of the first current source circuitry, the control terminal of the third transistor is coupled to the second terminal of the first frequency multiplier circuitry;
a second inductor having a first terminal and a second terminal; and
a second capacitor having a first terminal and a second terminal, the first terminal of the second capacitor is coupled to the control terminal of the second transistor, second terminal of the third transistor, the second terminal of the amplifier, and the first terminal of the second inductor, the second terminal of the second capacitor is coupled to the second terminal of the second inductor.

8. The apparatus of claim 1, wherein the inductor is a first inductor, the capacitor is a first capacitor, the second transistor further has a control terminal, the terminal of the amplifier is a first terminal, the amplifier further has a second terminal, and the apparatus further comprising:
a third transistor having a first terminal, a second terminal, and a control terminal, the first terminal of the third transistor is coupled to the terminal of the second current source circuitry and the first terminal of the second transistor, the control terminal of the third transistor is coupled to the second terminal of the first transistor, the second terminal of the first inductor, the second terminal of the first capacitor, and the first terminal of the amplifier;
a second inductor having a first terminal and a second terminal; and
a second capacitor having a first terminal and a second terminal, the first terminal of the capacitor is coupled to the control terminal of the second transistor, second terminal of the third transistor, the second terminal of the amplifier, and the first terminal of the second inductor, the second terminal of the capacitor is coupled to the second terminal of the second inductor.

9. An apparatus comprising:
first frequency multiplier circuitry having a terminal; and
second frequency multiplier circuitry having a first terminal and a second terminal, the first terminal of the second frequency multiplier circuitry coupled to the terminal of the first frequency multiplier circuitry, the second frequency multiplier circuitry configured to generate a clock signal having a duty cycle;
duty cycle estimation circuitry having a first terminal and a second terminal, the duty cycle estimation circuitry configured to estimate the duty cycle of the clock signal; and
duty cycle correction circuitry having a first terminal, a second terminal, and a third terminal, the first terminal of the duty cycle correction circuitry coupled to the second terminal of the second frequency multiplier circuitry, the second terminal of the duty cycle correction circuitry coupled to the first terminal of the duty cycle estimation circuitry, the third terminal of the duty cycle correction circuitry is coupled to the second terminal of the duty cycle estimation circuitry, the duty cycle correction circuitry configured to adjust the duty cycle of the clock signal responsive to the estimate of the duty cycle from the duty cycle estimation circuitry.

10. The apparatus of claim 9, wherein the terminal of the first frequency multiplier circuitry is a first terminal, the first frequency multiplier circuitry further having a second terminal, the apparatus further comprising oscillator circuitry having a terminal coupled to the second terminal of the first frequency multiplier circuitry.

11. The apparatus of claim 9, wherein the second frequency multiplier circuitry comprising:
a first transistor having a first terminal and a control terminal, the control terminal of the first transistor is coupled to the terminal of the first frequency multiplier circuitry;
current source circuitry having a terminal;
a second transistor having a first terminal and a second terminal, the first terminal of the second transistor is coupled to the terminal of the current source circuitry;
an inductor having a first terminal and a second terminal;
a capacitor having a first terminal and a second terminal, the first terminal of the capacitor is coupled to the first terminal of the inductor; and
an amplifier having a first terminal and a second terminal, the first terminal of the amplifier coupled to the first terminal of the first transistor, the second terminal of the second transistor, the second terminal of the inductor, and the second terminal of the capacitor, the second terminal of the amplifier coupled to the first terminal of the duty cycle correction circuitry.

12. The apparatus of claim 11, wherein the terminal of the first frequency multiplier circuitry is a first terminal, the first frequency multiplier circuitry further having a second terminal, the current source circuitry is first current source circuitry, the first transistor further has a second terminal, the inductor is a first inductor, the capacitor is a first capacitor, the second transistor further has a control terminal, the amplifier further has a third terminal, and the apparatus further comprising:
second current source circuitry having a terminal;
a third transistor having a first terminal, a second terminal, and a control terminal, the first terminal of the third transistor is coupled to the second terminal of the first transistor and the terminal of the second current source circuitry, the control terminal of the third transistor is coupled to the second terminal of the first frequency multiplier circuitry;
a second inductor having a first terminal and a second terminal; and
a second capacitor having a first terminal and a second terminal, the first terminal of the second capacitor is coupled to the control terminal of the second transistor, second terminal of the third transistor, the third terminal of the amplifier, and the first terminal of the second inductor, the second terminal of the second capacitor is coupled to the second terminal of the second inductor.

13. The apparatus of claim 9, wherein the duty cycle estimation circuitry comprising:
ring counter circuitry having a first terminal, and a second terminal, the first terminal of the ring counter circuitry coupled to the second terminal of the duty cycle correction circuitry;
multiplexer circuitry having a first terminal and a second terminal, the first terminal of the multiplexer circuitry coupled to the second terminal of the ring counter circuitry;
filter circuitry having a first terminal and a second terminal, the first terminal of the filter circuitry coupled to the second terminal of the multiplexer circuitry;
comparator circuitry having a first terminal and a second terminal, the first terminal of the comparator circuitry coupled to the second terminal of the filter circuitry; and
coefficient controller circuitry having a first terminal and a second terminal, the first terminal of the coefficient controller circuitry coupled to the second terminal of the comparator circuitry, the second terminal of the coefficient controller circuitry coupled to the third terminal of the duty cycle correction circuitry.

14. The apparatus of claim 9, wherein the duty cycle correction circuitry comprising:
programmable delay circuitry having a first terminal and a second terminal, the first terminal of the programmable delay circuitry coupled to the second terminal of the second frequency multiplier circuitry; and
multiplexer circuitry having a terminal coupled to the second terminal of the programmable delay circuitry.

15. The apparatus of claim 9, further comprising transmitter circuitry having a terminal coupled to the second terminal of the duty cycle correction circuitry and the first terminal of the duty cycle estimation circuitry.

16. An apparatus comprising:
clock multiplier circuitry configured to multiply a frequency of a first clock signal to generate a second clock signal; and
injection multiplication circuitry coupled to the clock multiplier circuitry, the injection multiplication circuitry configured to:
generate an injection current responsive to amplitudes of the second clock signal;
modify a resonant frequency of the injection multiplication circuitry by supplying the injection current; and
generate a third clock signal having a frequency set by the resonant frequency.

17. The apparatus of claim 16, further comprising duty cycle correction circuitry coupled to the injection multiplication circuitry, the duty cycle correction circuitry configured to:
delay rising edges of the third clock signal by first delay values; and
delay falling edges of the third clock signal by second delay values.

18. The apparatus of claim 17, further comprising duty cycle estimation circuitry coupled to the duty cycle correction circuitry, the duty cycle estimation circuitry configured to:
compare a first duration of a first cycle of the third clock signal to a second duration of a second cycle of the third clock signal;
determine the first delay values responsive to comparing the first duration and the second duration; and
determine the second delay values responsive to comparing the first duration and the second duration.

19. The apparatus of claim 17, further comprising duty cycle estimation circuitry coupled to the duty cycle correction circuitry, the duty cycle estimation circuitry configured to:
determine a first duration of a first harmonic of the third clock signal, the first harmonic of the third clock signal determined by the frequency of the first clock signal;
determine a second duration of a second harmonic of the third clock signal, the second harmonic of the third clock signal determined by the frequency of the first clock signal; and
determine variations in a duty cycle of the third clock signal responsive comparing the first duration to the second duration.

20. The apparatus of claim 19, the duty cycle correction circuitry further configured to:
generate a first voltage responsive to low pass filtering the first duration;
generate a second voltage responsive to low pass filtering the second duration; and
determine variations in the duty cycle to be proportional to a difference between the first voltage and the second voltage.
